(19) United States
(12) Patent Application Publication
(10) Pub. No.: US 2007/0007883 A1
(43) Pub. Date: Jan. 11, 2007

(54) Gravure plate, method for forming light-emitting layer or hole-injection layer using the same, and organic light-emitting device

(75) Inventors: Toshihiko Takeda, Tokyo-To (JP); Shigeru Morito, Tokyo-To (JP); Masaru Kobayashi, Tokyo-To (JP); Hiroyuki Shirogane, Tokyo-To (JP)

Correspondence Address: OLIFF & BERRIDGE, PLC, P.O. BOX 19928, ALEXANDRIA, VA, 22320, US

(73) Assignee: DAI NIPPON PRINTING CO., LTD., Tokyo-To (JP)

(21) Appl. No.: 11/482,160

(22) Filed: Jul. 7, 2006

(30) Foreign Application Priority Data
Jul. 11, 2005 (JP) 2005-201189

(51) Int. Cl. H01J 1/62

(52) U.S. Cl. 313/503

(57) ABSTRACT

A gravure plate useful in forming a light-emitting layer and/or a hole-injection layer of an organic light-emitting device has a plurality of cells in the shape of stripes, and non-cell portions between the cells. The proportion of the width b of each cell measured in the direction of printing to the width a of each cell measured in the direction perpendicular to the direction of printing, b/a, is 0.6 or more, and the proportion of the length L of each cell to the length S of each non-cell portion, L/S, is from 0.8 to 100. The length L of each cell is from 10 to 500 μm, the length S of each non-cell portion is from 2 to 500 μm, and the depth of the gravure plate is from 20 to 200 μm.

### BACKGROUND OF THE INVENTION

1. Field of the Invention

The present invention relates to a gravure plate useful in forming, by gravure offset printing, a light-emitting layer and a hole-injection layer, components of an organic light-emitting device, to a method for forming a light-emitting layer or a hole-injection layer, and to an organic light-emitting device.

2. Background Art

Organic electroluminescence (EL) devices (organic light-emitting devices) have the following advantages: they are excellent in visibility because they are self-luminous; they are wholly solid displays unlike liquid crystal displays; they are scarcely affected by changes in temperature; they have great viewing angles; and so forth. In recent years, they have come to be put into practical use as organic light-emitting devices such as full-color displays, area-color displays, and illuminations.

Organic light-emitting devices have light-emitting layers, and organic light-emitting materials for the light-emitting layers are classified into low-molecular-weight light-emitting materials and high-molecular-weight light-emitting materials. For example, a high-molecular-weight light-emitting layer can be formed by any of a variety of printing methods or an ink-jet deposition method, using light-emitting-layer-forming ink containing an organic light-emitting material.

Examples of the above printing methods include offset printing using thixotropic organic-light-emitting-material-containing ink having a coefficient of viscosity of 100 to 60000 cP, in which a silicone blanket is made to receive the ink from an intaglio printing plate, and the ink on the blanket is then transferred to a substrate in sheet form to form thereon a light-emitting layer (Patent Document 1).

Another method is offset printing using ink containing an organic light-emitting material dissolved in a solvent having a water-solubility of 5% by weight or less, in which a blanket is made to receive the ink from an intaglio printing plate, and the ink on the blanket is then transferred to a substrate to form thereon a light-emitting layer (Patent Document 2).

A further method for forming a light-emitting layer is as follows: ink containing an organic light-emitting material is supplied to the surface of a silicone blanket via a gravure roll to form a coating film; a relief printing plate is pressed onto this coating film to remove those portions of the coating film with which the relief printing plate is brought into contact; the coating film remaining on the surface of the silicone blanket is then transferred to a face to be coated with the film, thereby forming a light-emitting layer on this face (Patent Document 3).

A still further method for forming a light-emitting layer is intaglio offset printing using ink containing an organic light-emitting material and a blanket made from a silicone elastomer that undergoes a volume change of below 40% when immersed in a solvent to be used for the ink, in which the ink is transferred to the blanket from recesses in an intaglio printing plate and is then further transferred to a substrate to form thereon a light-emitting layer (Patent Document 4).

These methods for forming a light-emitting layer are employed to form hole-injection layers as well.

Patent Document 1: Japanese Laid-Open Patent Publication No. 93668/2001.

Patent Document 2: Japanese Laid-Open Patent Publication No. 291587/2001.

Patent Document 3: Japanese Laid-Open Patent Publication No. 178915/2004.

Patent Document 4: Japanese Laid-Open Patent Publication No. 308973/2003.

However, the above-described conventional methods for forming a light-emitting layer or a hole-injection layer, using a gravure plate or an intaglio printing plate, use ink having relatively high viscosity, so that when filling recesses in an intaglio printing plate with the ink by the use of a doctor blade, part of the ink tends to be left on the non-recessed portions of the printing plate without being scraped off with the doctor blade, or the ink layer formed tends to be non-uniform in thickness. It has thus been difficult to form, by the conventional methods, light-emitting layers uniform in thickness. If the viscosity of the ink is decreased in order to solve this problem, the ink concentration is reduced, and the ink is transferred in a decreased amount. Therefore, it has so far been difficult to form a light-emitting layer with a thickness as great as 70 nm or more and a hole-injection layer with a thickness as great as 50 nm or more. Further, since the ink readily penetrates the silicone blanket, the conventional methods have been disadvantageous in that the light-emitting layer or hole-injection layer formed has a roughened surface and that the plate wear of the silicone blanket is impaired.

On the other hand, by spin-coating a substrate with ink containing an organic light-emitting or hole-injection material and drying the ink, it is possible to form a light-emitting layer or a hole-injection layer uniform in thickness. However, to form a light-emitting layer or a hole-injection layer in the desired pattern by spin coating, it is necessary to combine a spin coating process with a photolithographic process, so that the whole process gets complicated. In addition, there has been a problem that the ink is used only at a decreased efficiency. On the contrary, it is easy to form pattern-wise a light-emitting layer or a hole-injection layer by an ink-jet deposition method. However, unless the fluidity, the surface tension, or the like of the ink to be jetted is well controlled, it has been difficult to form a light-emitting layer or a hole-injection layer uniform in thickness.

Further, a conventional organic light-emitting device for use as a full-color or area-color display has been insufficient in luminance and emission efficiency because the thickness of its light-emitting layer or hole-injection layer is non-uniform or not satisfactorily great as described above. Such a device has had limitations to improvement in display performance and has not been highly reliable.

### SUMMARY OF THE INVENTION

The present invention has been accomplished in the light of the above-described problems in the prior art. Accordingly, an object of the present invention is to provide a gravure plate useful in forming a light-emitting layer or a hole-injection layer in the desired pattern, having a great and uniform thickness; a method for forming a light-emitting layer or a hole-injection layer, using the gravure plate; and a highly-reliable organic light-emitting device excellent in display performance.

The present invention is a gravure plate useful in forming a light-emitting layer and/or a hole-injection layer of an organic light-emitting device, comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm.

The present invention is a gravure plate useful in forming a light-emitting layer and/or a hole-injection layer of an organic light-emitting device, comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm.

The present invention is a method for forming a light-emitting layer of an organic light-emitting device that comprises electrodes facing each other, and a light-emitting device layer having at least a light-emitting layer, formed between the facing electrodes, by the use of a gravure plate comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a light-emitting-layer-forming ink composition containing at least an organic light-emitting material and a solvent, and after letting a blanket receive the light-emitting-layer-forming ink composition from the cells, transferring the light-emitting-layer-forming ink composition on the blanket to a face to be coated with a light-emitting layer, the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension of 40 dyne/cm or less and a boiling point of 150 to 250° C.

The present invention is the method for forming a light-emitting layer, in which the resin film has a thickness ranging from 5 to 200 μm.

The present invention is the method for forming a light-emitting layer, in which the blanket has a blanket cylinder and a resin film integrally formed around the periphery of the blanket cylinder.

The present invention is the method for forming a light-emitting layer, in which the blanket has a blanket cylinder, and a resin film that winds round the rotating blanket cylinder in the section including at least a point at which the blanket receives the light-emitting-layer-forming ink composition from the gravure plate and a point at which the light-emitting-layer-forming ink composition is transferred to the face to be coated with a light-emitting layer.

The present invention is the method for forming a light-emitting layer, in which the blanket cylinder has, on its surface, a cushion layer.

The present invention is the method for forming a light-emitting layer, in which the content of the organic light-emitting material in the light-emitting-layer-forming ink composition is from 1.5 to 4.0% by weight.

The present invention is the method for forming a light-emitting layer, in which, in the gravure plate, a multitude of the cells form one area-color pattern, and the one pattern has a width of 200 μm or more.

The present invention is the method for forming a light-emitting layer, in which a plurality of light-emitting layers that emit light of different colors are sequentially formed by using two or more sets of the gravure plate and the blanket.

The present invention is the method for forming a light-emitting layer, in which the gravure plate is divided in the axial direction into a plurality of sections, and any light-emitting-layer-forming ink composition is supplied to each section, thereby simultaneously forming a plurality of light-emitting layers that emit light of different colors.

The present invention is a method for forming a hole-injection layer of an organic light-emitting device that comprises electrodes facing each other, and a light-emitting device layer having at least a hole-injection layer, formed between the facing electrodes, by the use of a gravure plate comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a hole-injection-layer-forming ink composition containing at least a hole injection material and a solvent, and after letting a blanket receive the hole-injection-layer-forming ink composition from the cells, transferring the hole-injection-layer-forming ink composition on the blanket to a face to be coated with a hole-injection layer, the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

The present invention is the method for forming a hole-injection layer, in which the resin film has a thickness ranging from 5 to 200 μm.

The present invention is the method for forming a hole-injection layer, in which the blanket has a blanket cylinder and a resin film integrally formed around the periphery of the blanket cylinder.

The present invention is the method for forming a hole-injection layer, in which the blanket has a blanket cylinder, and a resin film that winds round the rotating blanket cylinder in the section including at least a point at which the blanket receives the hole-injection-layer-forming ink composition from the gravure plate and a point at which the hole-injection-layer-forming ink composition is transferred to the face to be coated with a hole-injection layer.

The present invention is the method for forming a hole-injection layer, in which the blanket cylinder has, on its surface, a cushion layer.

The present invention is the method for forming a hole-injection layer, in which the content of the hole-injection material in the hole-injection-layer-forming ink composition is from 0.3 to 10.0% by weight.

The present invention is an organic light-emitting device comprising a transparent substrate; a transparent electrode layer formed in the desired pattern on the transparent substrate; an insulating layer having a plurality of openings in which the desired portions of the transparent electrode layer formed on the transparent substrate are exposed; a light-emitting device layer having at least a light-emitting layer and a hole-injection layer, formed to cover the transparent electrode layer exposed at the bottom of the openings; and an electrode layer formed so that it is in contact with the light-emitting device layer situated in the desired openings, the light-emitting layer of the light-emitting device layer being formed by a method for forming a light-emitting layer of an organic light-emitting device that comprises electrodes facing each other, and a light-emitting device layer having at least a light-emitting layer, formed between the facing electrodes, by the use of a gravure plate comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a light-emitting-layer-forming ink composition containing at least an organic light-emitting material and a solvent, and after letting a blanket receive the light-emitting-layer-forming ink composition from the cells, transferring the light-emitting-layer-forming ink composition on the blanket to a face to be coated with a light-emitting layer, the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension of 40 dyne/cm or less and a boiling point of 150 to 250° C., the hole-injection layer of the light-emitting device layer being formed by a method for forming a hole-injection layer of an organic light-emitting device that comprises electrodes facing each other, and a light-emitting device layer having at least a hole-injection layer and a light-emitting layer, formed between the facing electrodes, by the use of a gravure plate comprising a plurality of cells in the shape of stripes, and non-cell portions between the cells, the proportion of the width b of the cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a hole-injection-layer-forming ink composition containing at least a hole-injection material and a solvent, and after letting a blanket receive the hole-injection-layer-forming ink composition from the cells, transferring the hole-injection-layer-forming ink composition on the blanket to a face to be coated with a hole-injection layer, the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

The present invention is an organic light-emitting device comprising a substrate; a electrode layer formed in the desired pattern on the substrate; an insulating layer having a plurality of openings in which the desired portions of the electrode layer formed on the substrate are exposed; a light-emitting device layer having at least a light-emitting layer and a hole-injection layer, formed to cover the electrode layer exposed at the bottom of the openings; and a transparent electrode layer formed so that it is in contact with the light-emitting device layer situated in the desired openings, the light-emitting layer of the light-emitting device layer being formed by a method for forming a light-emitting layer of an organic light-emitting device that comprises electrodes facing each other, and a light-emitting device layer having at least a light-emitting layer, formed between the facing electrodes, by the use of a gravure plate comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a light-emitting-layer-forming ink composition containing at least an organic light-emitting material and a solvent, and after letting a blanket receive the light-emitting-layer-forming ink composition from the cells, transferring the light-emitting-layer-forming ink composition on the blanket to a face to be coated with a light-emitting layer, the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension or 40 dyne/cm or less and a boiling point of 150 to 250° C., the hole-injection layer of the light-emitting device layer being formed by a method for forming a hole-injection layer of an organic light-emitting device that comprises electrodes facing each other, and a light-emitting device layer having at least a hole-injection layer and a light-emitting layer, formed between the facing electrodes, by the use of a gravure plate comprising a plurality of cells in the shape of stripes, and non-cell portions between the cells, the proportion of the width b of each cell measured in the direction of printing to the width a of the cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of the cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a hole-injection-layer-forming ink composition containing at least a hole-injection material and a solvent, and after letting a blanket receive the hole-injection-layer-forming ink composition from the cells, transferring the hole-injection-layer-forming ink composition on the blanket to a face to be coated with a hole-injection layer, the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

The present invention is the organic light-emitting device, in which the light-emitting layer and the hole-injection layer, constituent layers of the light-emitting device layer, have a thickness of 70 nm or more and a thickness of 50 nm or more, respectively.

The present invention is the organic light-emitting device, in which the light-emitting device layer consists of at least the hole-injection layer, the light-emitting layer, and an electron-injection layer that are laminated in the order stated.

The present invention is the organic light-emitting device of passive matrix type.

The present invention is the organic light-emitting device of active matrix type.

The present invention is the organic light-emitting device, in which the openings in the insulating layer have organic light-emitting posters with a maximum opening width of 10 mm or more.

The present invention is the organic light-emitting device further comprising a color filter layer formed on the transparent substrate or on the substrate.

The present invention is the organic light-emitting device further comprising a color-changing phosphor layer formed on the color filter layer.

The present invention is the organic light-emitting device, in which the light-emitting device layer emits light of the desired color including white, or light of the two or more desired colors that form a predetermined pattern.

The present invention is the organic light-emitting device, in which the light-emitting device layer emits blue light, and the color-changing phosphor layer has a green color-changing layer that changes the blue light into green fluorescence and emits this green fluorescence and a red color-changing layer that changes the blue light into red fluorescence and emits this red fluorescence.

The present invention is the organic light-emitting device, in which the hole-injection layer and the light-emitting layer that are formed in the following manner where a film for the light-emitting layer is formed within one minute after forming a film for the hole-injection layer, and these two films are simultaneously dried at a temperature of 100 to 200° C.

By the use of the gravure plate of the present invention, it is possible to form a light-emitting layer and a hole-injection layer that are uniform in thickness and have the desired thicknesses.

The method for forming a light-emitting layer according to the present invention makes it possible to form a light-emitting layer having a uniform thickness as great as 70 nm or more, and, moreover, form light-emitting layers that emit light of different colors, each light-emitting layer in the desired pattern. The method for forming a hole-injection layer according to the present invention makes it possible to form a hole-injection layer in the desired pattern, having a uniform thickness as great as 50 nm or more. Moreover, these methods of the invention make it possible to form a light-emitting layer and a hole-injection layer on a flexible substrate such as a resin film substrate. In addition, the blanket for use in the methods of the invention is excellent in plate wear and can contribute to the reduction of the cost of production of an organic light-emitting device.

Further, the light-emitting layer and the hole-injection layer of an organic light-emitting device of the present invention have thicknesses that are great and uniform because they are formed by the methods of the present invention, so that the luminance and the emission efficiency of the light-emitting device layer at the time of emission of light are high. Therefore, the organic light-emitting device of the invention is excellent in display performance and reliability.

### BRIEF DESCRIPTION OF THE DRAWINGS

FIG. 1 is a view for explaining an embodiment of a gravure plate of the present invention.

FIGS. 2 (A)(B)(C) are views view for explaining the proportion of the width b of a cell measured in the direction of printing to the width a of the cell measured in the direction perpendicular to the direction of printing, b/a, in a gravure plate of the present invention.

FIG. 3 is a view for explaining another embodiment of a gravure plate of the present invention.

FIG. 4 is a view for explaining a further embodiment of a gravure plate of the present invention.

FIG. 5 is a view for explaining a still further embodiment of a gravure plate of the present invention.

FIG. 6 is a view for explaining a method for forming a light-emitting layer or a hole-injection layer according to the present invention.

FIG. 7 is a view for explaining another method for forming a light-emitting layer or a hole-injection layer according to the present invention.

FIG. 8 is a view for explaining a further method for forming a light-emitting layer or a hole-injection layer according to the present invention.

FIG. 9 is a view for explaining cells in a gravure plate.

FIG. 10 is a view for explaining a method for forming a light-emitting layer according to the present invention.

FIG. 11 is a view for explaining another method for forming a light-emitting layer according to the present invention.

FIG. 12 is a partial sectional perspective view showing an embodiment of an organic light-emitting device of the present invention.

FIG. 13 is a plane view showing another embodiment of an organic light-emitting device of the present invention.

FIG. 14 is a view showing the relationship between a light-emitting layer and openings in an insulating layer.

FIG. 15 is a perspective view showing a further embodiment of an organic light-emitting device of the present invention.

FIG. 16 is a sectional view of the organic light-emitting device shown in FIG. 15, taken along line A-A of FIG. 15.

FIG. 17 is a partial sectional view showing a still further embodiment of an organic light-emitting device of the present invention.

FIG. 18 is a partial sectional view showing a yet further embodiment of an organic light-emitting device of the present invention.

### BEST MODE FOR CARRYING OUT THE INVENTION

The present invention will be described hereinafter with reference to the accompanying drawings.

[Gravure Plate]

A gravure plate of the present invention is useful in forming a light-emitting layer and/or a hole-injection layer of an organic light-emitting device.

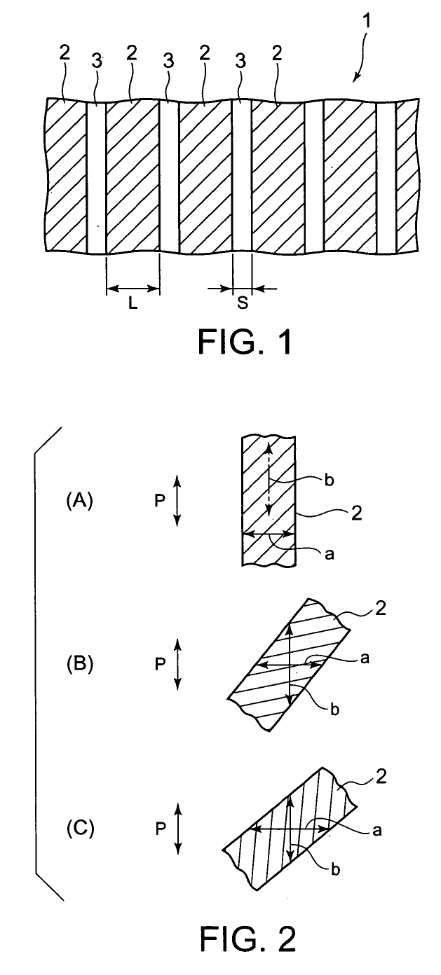

FIG. 1 is a view for explaining an embodiment of a gravure plate of the present invention. The gravure plate 1 of the present invention comprises a plurality of cells 2 in the shape of stripes, and non-cell portions 3 between the cells 2. The proportion of the width of each cell 2 (the length L of each cell, also referred to as the length of a cell portion), the portion depicted with oblique lines, to the width of each non-cell portion 3 (the length S of each non-cell portion), L/S, is from 0.8 to 100, preferably from 1 to 60. The width of each cell 2 (the length L of each cell portion) is from 10 to 500 μm, preferably from 30 to 300 μm; the width of each non-cell portion 3 (the length S of each non-cell portion) is from 2 to 500 μm, preferably from 5 to 200 μm; and the depth of the cells 2 (the depth of the gravure plate) is from 20 to 200 μm, preferably from 30 to 100 μm.

Further, as shown in FIGS. 2(A) to 2(C), in the gravure plate 1 of the present invention, the proportion of the width b of each cell 2 (the portion depicted with oblique lines) measured in the direction of printing (the direction indicated by the arrow P in the figures) to the width a of the cell 2 measured in the direction perpendicular to the direction of printing, b/a, is 0.6 or more, preferably 0.8 or more, and this proportion has no upper limit. In the present invention, the direction of printing is synonymous with the direction of rotation of the gravure plate.

That the above-described proportion of the length L of each cell portion to the length S of each non-cell portion, L/S, does not fall in the above-described range is unfavorable because it is difficult to form a thick film when this proportion L/S is less than 0.8, and, when the proportion L/S is more than 100, it is difficult to make the cells in the gravure plate, and variations in film thickness become great. When the width of each cell 2 (the length L of each cell portion) is less than 10 μm, it is difficult to form a thick film; while when this width exceeds 500 μm, variations in film thickness become great. Thus, a width of each cell 2 not in the above-described range is unfavorable. When the width of each non-cell portion 3 (the length S of each non-cell portion) is less than 2 μm, it is difficult to make cells in the gravure plate; while when this width exceeds 500 μm, variations in film thickness become great, and it becomes difficult to form a thick film. Thus, a width of each non-cell portion 3 not in the above-described range is unfavorable.

Further, when the depth of the cells 2 (the depth of the gravure plate) is less than 20 μm, it is difficult to form a thick film; and even if this depth is made as great as more than 200 μm, a film with an increased thickness cannot be obtained. Furthermore, when the proportion b/a is less than 0.6, it is difficult to form a thick film, so that it is not easy to form a light-emitting layer with a thickness of 70 nm or more and a hole-injection layer with a thickness of 50 nm or more in the steps of forming a light-emitting layer and a hole-injection layer, respectively, that will be described later. A proportion b/a not in the above-described range is thus unfavorable.

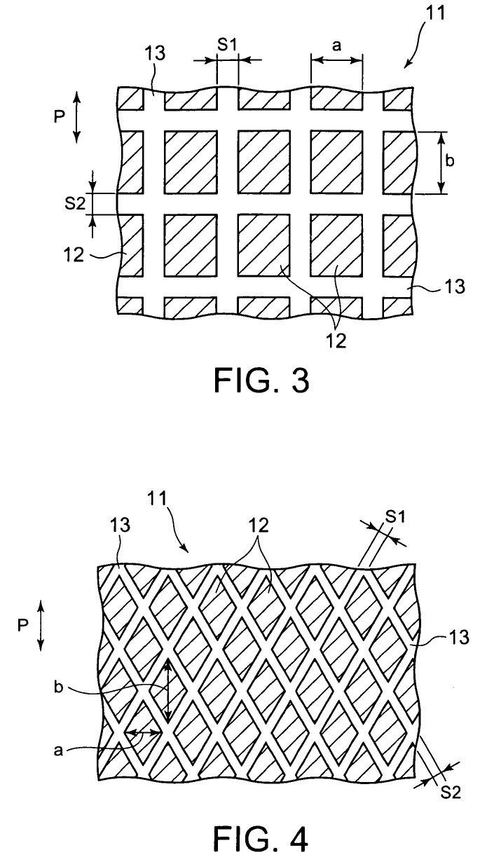

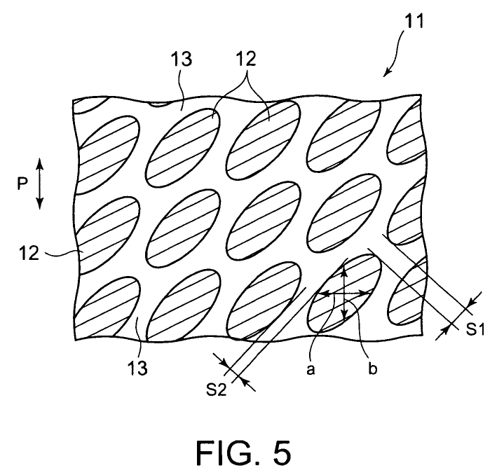

FIG. 3 is a view for explaining another embodiment of a gravure plate of the present invention. The gravure plate 11 shown in FIG. 3 comprises narrow-belt-shaped non-cell portions 13 that cross each other to form a grid, and a plurality of cells 12 defined by the non-cell portions 13. Namely, the cells 12 are in the form of a plurality of divided sections (in the embodiment shown in the figure, each cell 12 is in the shape of a regular square), and the non-cell portions 13 are present between the cells 12. FIG. 4 is a view for explaining a further embodiment of a gravure plate of the present invention. The gravure plate 11 shown in FIG. 4 has cells 12 in the form of a plurality of divided sections, each cell 12 in the shape of a rhombus, and non-cell portions 13 are present between the cells 12. FIG. 5 is a view for explaining a still further embodiment of a gravure plate of the present invention. The gravure plate 11 shown in FIG. 5 has cells 12 in the form of a plurality of divided sections, each cell 12 in the shape of an oval, and non-cell portions 13 are present between the cells 12.

In the above-described gravure plates 11 shown in FIGS. 3 to 5, the proportion of the maximum width b of each cell 12 (each portion depicted with oblique lines) measured in the direction of printing (the direction indicated by the arrow P in the figures) to the maximum width a of each cell 12 measured in the direction perpendicular to the direction of printing, b/a, is 0.6 or more, preferably 0.8 or more, and this proportion has no upper limit. Further, the percentage of the whole cell area to the film-formed area is from 55 to 95%, preferably from 60 to 90%; the width of each non-cell portion 13 (the length S1, S2 of each non-cell portion) is from 2 to 500 μm, preferably from 10 to 200 μm; and the depth of the cells 12 (the depth of the gravure plate) is from 20 to 200 μm, preferably from 30 to 100 μm.

When the above-described proportion b/a is less than 0.6, it is difficult to form a thick film, so that it is not easy to form a light-emitting layer with a thickness of 70 nm or more and a hole-injection layer with a thickness of 50 nm or more in the steps of forming a light-emitting layer and a hole-injection layer, respectively, that will be described later. A proportion b/a not in the above-described range is thus unfavorable. Further, when the percentage of the whole cell area to the film-formed area is less than 55%, it is difficult to form a thick film, while when this percentage exceeds 95%, variations in film thickness become great. To make this percentage less than 55% or more than 95% is thus unfavorable. When the width of each non-cell portion 13 (the length S1, S2 of each non-cell portion) is less than 2 μm, it is difficult to make cells in the gravure plate, and when this width exceeds 500 μm, variations in film thickness become great, and it becomes difficult to form a thick film. It is thus unfavorable for the non-cell portions 13 to have a width not in the above-described range. When the depth of the cells 12 (the depth of the gravure plate) is less than 20 μm, it is difficult to form a thick film, and even if this depth is made as great as more than 200 μm, a film with an increased thickness cannot be obtained.

The above-described shapes of the cells in the gravure plates are only examples and never restrict the present invention.

[Method for Forming Light-Emitting Layer or Hole-Injection Layer]

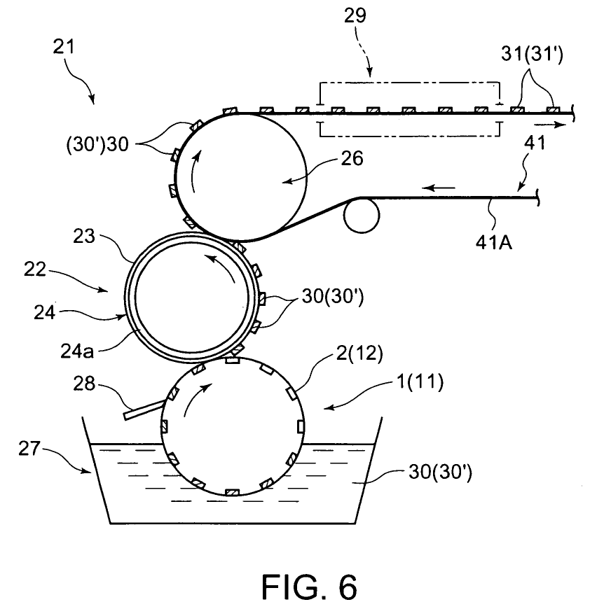

FIG. 6 is a view for explaining a method for forming a light-emitting layer or a hole-injection layer according to the present invention. In FIG. 6, a light-emitting-layer-forming ink composition 30 or a hole-injection-layer-forming ink composition 30′ placed in an ink pan 27, a component part of a printing unit 21, is supplied to the surface of a rotating gravure plate 1 (11), while scraping the excess ink composition 30, 30′ off with a doctor blade 28, thereby filling in cells 2 (12) with the ink composition 30, 30′. A blanket 22 receives the ink composition 30, 30′ from the cells 2 (12), and the received ink composition 30, 30′ is then transferred to the surface 41A, to be coated with a light-emitting layer or a hole-injection layer, of a substrate 41 running on an impression drum 26. This substrate 41 is carried to a drying zone 29, where the ink composition 30, 30′ is dried to form a light-emitting layer 31 or a hole-injection layer 31′.

In this method, the aforementioned gravure plate of the present invention is used as the gravure plate 1 (11), so that explanation of the gravure plate 1 (11) is not given here.

Further, in the present invention, the blanket 22 has a blanket cylinder 24, and a resin film 23 having a surface tension of 35 dyne/cm or more, preferably from 35 to 65 dyne/cm, integrally formed around the periphery of the blanket cylinder 24.

The light-emitting-layer-forming ink composition 30 for use in the present invention has a coefficient of viscosity of 5 to 200 cP (ink temperature: 23° C.), preferably 20 to 150 cP, at a shear rate of 100 sec⁻¹, and contains a solvent having a surface tension of 40 dyne/cm or less, preferably from 20 to 37 dyne/cm, and a boiling point between 150° C. and 250° C., preferably between 170° C. and 230° C.

The coefficient of viscosity of the hole-injection-layer-forming ink composition 30′ for use in the present invention at a shear rate of 100 sec⁻¹ (ink temperature: 23° C.) is from 1 to 100 cP, preferably from 3 to 30 cP. The dynamic surface tension of the ink composition 30′ at 2 Hz (ink temperature: 23° C.) is 40 dyne/cm or less, preferably 35 dyne/cm or less, and it has no lower limit. Further, the solvent for use in the hole-injection-layer-forming ink composition 30′ is a solvent mixture of water and an alcoholic solvent. The boiling point of the alcoholic solvent is from 60 to 250° C., and the alcoholic solvent content of the solvent mixture is from 5 to 70% by weight, preferably from 10 to 50% by weight.

(Resin Film)

When the surface tension of the resin film 23 forming the surface layer of the above-described blanket 22 is less than 35 dyne/cm, the ink receptivity of the resin film 23 from the gravure plate 1 (11) is insufficient. It is therefore difficult to form a light-emitting layer 31 or a hole-injection layer 31′ that is uniform in thickness. The surface tension of the resin film 23 (the surface tension of a solid [γs]) is determined by measuring the contact angle θ with an automatic contact angle meter (Drop Master Model 700 manufactured by Kyowa Kaimen Kagaku Kabushiki Kaisha, Japan), using as reference materials two or more liquids having known surface tensions, and calculating by using the equation: γs (surface tension of solid)=γSL (surface tension of liquid)cos θ+γSL (surface tension of solid and liquid).

Examples of the resin film 23 include resin films such as polyethylene terephthalate films, adherent polyethylene terephthalate films, corona-treated polyethylene terephthalate films, polyphenylene sulfide films, corona-treated polyphenylene sulfide films, polyethylene naphthalate films, adherent polyethylene naphthalate films, polynorbornene films, and melamine-baked polyethylene terephthalate films. The thickness of the resin film 23 may be between 5 μm and 200 μm, preferably between 10 μm and 100 μm, for example. A resin film 23 with a thickness of less than 5 μm is unfavorable, because such a film has impaired processability and cannot be easily wound around the blanket cylinder 24. On the other hand, a resin film 23 with a thickness of more than 200 μm is unfavorable as well, because such a resin film has excessively high hardness and decreased flexibility.

In the embodiment shown in the figure, the blanket cylinder 24 comprises a cushion layer 24a under the resin layer 23, the surface layer. The hardness of the cushion layer 24a is from 20 to 80°, for example, and the thickness of the cushion layer 24a is from 0.1 to 30 mm, for example. The above-described hardness is the Type A hardness that is determined by the durometer hardness test prescribed by JIS K-6253.

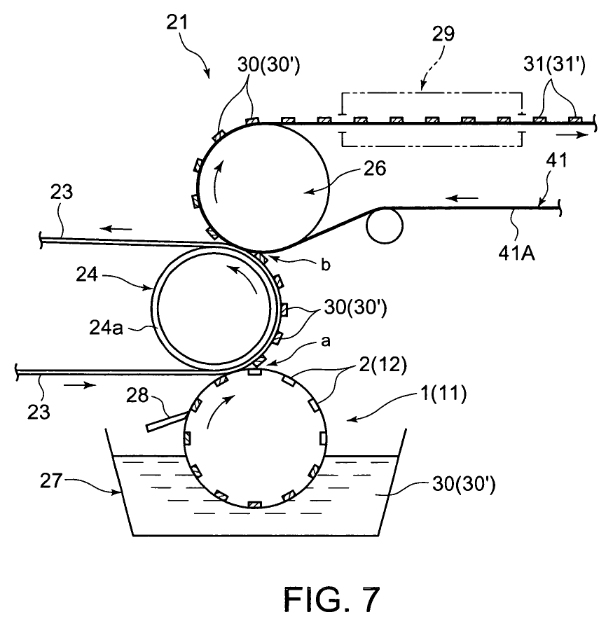

In the embodiment shown in FIG. 6, the resin film 23 is integrally formed around the blanket cylinder 24. Alternatively, the resin film 23 may also be made to run along the rotation of the blanket cylinder 24 so that it winds round the blanket cylinder 24, as shown in FIG. 7. In this case, it is necessary to make the resin film 23 wind round the blanket cylinder 24 in the section including at least a point at which the blanket receives the ink composition 30, 30′ from the gravure plate 1 (11) (the point indicated by the arrow a) and a point at which the ink composition 30, 30′ is transferred to the surface 41A to be coated with an ink film (the point indicated by the arrow b). Such a resin film 23 may be delivered from a delivery roll not shown in the figure to the blanket cylinder 24 and wound around a wind-up roll not shown in the figure. Alternatively, the resin film 23 may be prepared in the form of an endless film, and the endless film is made to run on a track between a roller not shown in the figure and the blanket cylinder 24.

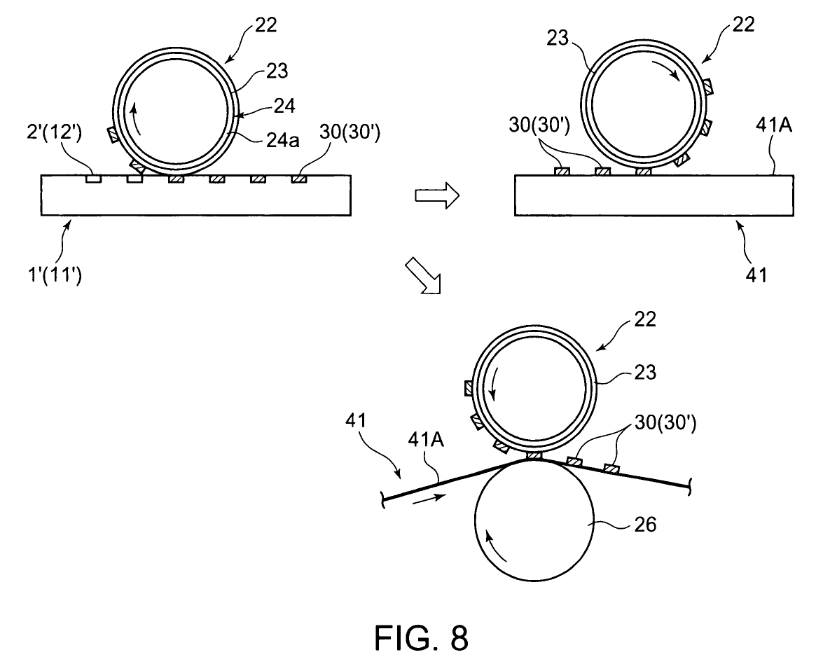

The gravure plate of the present invention may also be in the form of a sheet, and FIG. 8 shows an example of such an embodiment. In an embodiment shown in FIG. 8, an ink composition 30, 30′ is supplied to the surface of a gravure plate 1′ (11′) in the form of a sheet while scraping the excess ink composition 30, 30′ off with a doctor blade not shown in the figure, thereby filling in cells 2′ (12′) with the ink composition 30, 30′. Thereafter, a blanket 22 receives the ink composition 30, 30′ from the cells 2′ (12′), and the received ink composition 30, 30′ is transferred to the surface 41A, to be coated with an ink film, of a substrate 41 in sheet form, and is then dried to form a light-emitting layer or a hole-injection layer. Alternatively, the ink composition 30, 30′ may be transferred to the surface 41A, to be coated with an ink film, of the substrate 41 running on an impression drum 26 and dried to form a light-emitting layer or a hole-projection layer.

(Light-Emitting-Layer-Forming Ink Composition)

When the light-emitting-layer-forming ink composition 30 for use in the present invention has a coefficient of viscosity of less than 5 cP (ink temperature: 23° C.) at a shear rate of 100 sec⁻¹, runs occur, and it is difficult to form, with such an ink composition, a light-emitting layer with the desired thickness. On the other hand, when the ink composition 30 has a coefficient of viscosity of more than 200 cP, it forms a layer greatly roughened due to the cells in the gravure plate 1 (11), so that it is difficult to form, with such an ink composition, a light-emitting layer uniform in thickness. The coefficient of viscosity is measured with a viscoelasticity meter, Model MCR 301, manufactured by Physica Corp. at a temperature of 23° C. in the steady flow mode. It is preferred that the proportion of the coefficient of viscosity V1 of the light-emitting-layer-forming ink composition 30 (ink temperature: 23° C.) at a shear rate of 100 sec⁻¹ to the coefficient of viscosity V2 of the light-emitting-layer-forming ink composition 30 (ink temperature: 23° C.) at a shear rate of 1000 sec⁻¹, V1/V2, be approximately 0.9 to 1.5, which means that the ink composition is nearly a Newtonian fluid.

When the surface tension of the solvent used for the light-emitting-layer-forming ink composition 30 is in excess of 40 dyne/cm, the blanket 22 cannot sufficiently receive the light-emitting-layer-forming ink composition 30 from the gravure plate 1 (11), so that such a surface tension is unfavorable. Further, when the solvent used for the light-emitting-layer-forming ink composition 30 has a boiling point of less than 150° C., the light-emitting-layer-forming ink composition 30 transferred to the surface 41A, to be coated with a light-emitting layer, of the substrate 41 from the resin film 23, a component of the blanket 22, is immediately dried up, and the light-emitting layer 31 formed tends to have streaks. On the other hand, when the solvent has a boiling point of more than 250°, it is difficult to dry the ink composition 30, so that drying in a drying zone 29 affects the substrate 41 and so forth, or that the solvent can remain without being evaporated; such a high boiling point is thus unfavorable. The surface tension of the solvent is measured at a liquid temperature of 20° C. with a tension meter, Model CBVP-Z, manufactured by Kyowa Kaimen Kagaku Kabushiki Kaisha, Japan.

Examples of organic light-emitting materials useful for the light-emitting-layer-forming ink composition 30 include the following luminescent dyes, metal complexes, and polymers.

(1) Luminescent Dyes

Examples of luminescent dyes useful herein include cyclopentadiene derivatives, tetraphenylbutadiene derivatives, triphenylamine derivatives, oxadiazole derivatives, pyrazoloquinoline derivatives, distyryl benzene derivatives, distyryl arylene derivatives, silole derivatives, compounds having thiophene rings, compounds having pyridine rings, perynone derivatives, perylene derivatives, oligothiophene derivatives, trifumanylamine derivatives, oxadiazole dimers, and pyrazoline dimers.

(2) Luminescent Metal Complexes

Examples of luminescent metal complexes useful herein include metal complexes having, as a central metal, a metal such as Al, Zn, or Be, or a rare earth metal such as Tb, Eu, or Dy, and, as a ligand, oxadiazole, thiadiazole, phenylpyridine, phenylbenzoimidazole, or quinoline, such as alumiquinolinol complexes, benzoquinolinol beryllium complexes, benzoxazole zinc complexes, benzothiazole zinc complexes, azomethyl zinc complexes, porphyrin zinc complexes, and europium complexes.

(3) Luminescent Polymers

Examples of luminescent polymers useful herein include polyparaphenylenevinylene derivatives, polythiophene derivatives, polyparaphenylene derivatives, polysilane derivatives, polyacetylene derivatives, polyvinylcarbazole derivatives, and polyfluorene derivatives.

The content of the above-described organic light-emitting material in the light-emitting-layer-forming ink composition 30 may be made 1.5 to 4.0% by weight, for example.

A solvent having a surface tension that falls in the above-described range (40 dyne/cm or less) and a boiling point that falls in the above-described range (150 to 250° C.), such as cumene, anisole, n-propylbenzene, mesitylene, 1,2,4-trimethylbenzene, limonene, p-cymene, o-dichlorobenzene, butylbenzene, diethylbenzene, 2,3-dihydro-benzofurane, methyl benzoate, 1,2,3,4-tetramethylbenzene, amylbenzene, tetralin, ethyl benzoate, phenylhexane, cyclohexylbenzene, or butyl benzoate, can be used singly as the solvent for the light-emitting-layer-forming ink composition 30. In the case of a solvent mixture, a solvent mixture having a surface tension and a boiling point, calculated from the mixture ratio, that fall in the above-described respective ranges is used. For example, in the case of a 3:7 (weight basis) solvent mixture of a solvent 1 having a surface tension of A dyne/cm and a boiling point of B° C. and a solvent 2 having a surface tension of C dyne/cm and a boiling point of D°° C., the surface tension of the solvent mixture calculated from the mixture ratio [(A×3/10)+(C×7/10)] has to fall in the above-described range (40 dyne/cm or less), and the boiling point of the solvent mixture calculated from the mixture ratio [(B×3/10)+(D×7/10)] has to fall in the above-described range (150 to 250° C.). Individual solvents constituting the solvent mixture may therefore have surface tensions and boiling points that are not in the above-described respective ranges.

(Hole-Injection-Layer-Forming Ink Composition)

When the hole-injection-layer-forming ink composition 30′ for use in the present invention has a coefficient of viscosity of less than 1 cP (ink temperature: 23° C.) at a shear rate of 100 sec⁻¹, runs occur, and it is difficult to form, with such an ink composition, a hole-injection layer with the desired thickness. On the other hand, since a hole-injection-layer-forming ink composition 30′ having a coefficient of viscosity of more than 100 cP forms a layer greatly roughened due to the cells in the gravure plate 1 (11), it is difficult to form, with such an ink composition, a hole-injection layer uniform in thickness. The coefficient of viscosity of the hole-injection-layer-forming ink composition 30′ is measured by the same method as that employed to measure the coefficient of viscosity of the above-described light-emitting-layer-forming ink composition 30. Further, a hole-injection-layer-forming ink composition 30′ having a dynamic surface tension of more than 40 dyne/cm (ink temperature: 23° C.) at 2 Hz forms a layer greatly roughened due to the cells in the gravure plate 1 (11), so that it is difficult to form, with such an ink composition, a hole-injection layer uniform in thickness. The dynamic surface tension of the ink composition is determined by producing an air bubble in a liquid, and measuring the pressure that is exerted on the air bubble from the liquid (maximum bubble pressure method). Specifically, using SITA t60/2 (manufactured by SITA Messtechnik GmbH, Germany), an air bubble is produced at a temperature of 23° C. on a cycle of 2 Hz, and the dynamic surface tension value is read.

It is preferred that the proportion of the coefficient of viscosity V1 of the hole-injection-layer-forming ink composition 30′ (ink temperature: 23° C.) at a shear rate of 100 sec¹ to the coefficient of viscosity V2 of the hole-injection-layer-forming ink composition 30′ (ink temperature: 23° C.) at a shear rate of 1000 sec⁻¹, V1/V2, be approximately 0.9 to 1.3, and that the value obtained by dividing the dynamic surface tension of the hole-injection-layer-forming ink composition 30′ at 2 Hz by that of the hole-injection-layer-forming ink composition 30′ at 10 Hz be approximately 0.8 to 1.1, which mean that the hole-injection-layer-forming ink composition 30′ is nearly a Newtonian fluid.

An alcoholic solvent having a boiling point of 250° C. or less, such as one having a boiling point of 60 to 250° C., is used to prepare the solvent mixture of water and an alcoholic solvent for the hole-injection-layer-forming ink composition 30′. When an alcoholic solvent having a boiling point of more than 250° C. is used, it is difficult to dry the ink composition 30′, so that drying in a drying zone 29 affects the substrate 41 and so forth, or that the solvent can remain without being evaporated; such a high boiling point is thus unfavorable. Further, when a solvent mixture having an alcoholic solvent content of less than 5% by weight is used, the ink composition 30′ forms a roughened layer or causes cissing due the cells in the gravure plate, which makes it difficult to form a hole-injection layer uniform in thickness. On the other hand, when a solvent mixture having an alcoholic solvent content of more than 70% by weight is used, agglomerates tend to occur in the ink composition 30′, so that such a high alcoholic solvent content is unfavorable.

Examples of hole-injection materials useful for the hole-injection-layer-forming ink composition 30′ include phenylamine compounds, star-burst-type amine compounds, phthalocyanine compounds, oxides such as vanadium oxide, molybdenum oxide, ruthenium oxide, and aluminum oxide, amorphous carbon, polyaniline, polythiophene derivatives, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, polysilane compounds, aniline copolymers, and dielectric high-molecular-weight oligomers such as thiophene oligomers.

Hole-injection materials further include porphyrin compounds, aromatic tertiary amine compounds, and styrylamine compounds. Examples of the porphyrin compounds include porphine, 1,10,15,20-tetraphenyl-21H,23H-porphine copper (II), aluminum phthalocyanine chloride, and copper octamethylphthalocyanine. Examples of the aromatic tertiary amine compounds and the styrylamine compounds include N,N, N′,N′-tetraphenyl-4,4′-diaminophenyl, N,N-diphenyl-N,N′-bis(3-methylphenyl)-[1,1′-biphenyl]-4,4′-diamine, 4-(di-p-tolylamino)-4′-[4(di-p-tolylamino)styryl]stilbene, 3-methoxy-4′-N,N-diphenylamino-stilbenzene, 4,4′-bis[N-(1-naphthyl)-N-phenylamino]biphenyl, and 4,4′,4″-tris[N-(3-methylphenyl)-N-phenylamino]triphenylamine.

The content of the above-described hole-injection material in the hole-injection-layer-forming ink composition 30′ may be made 0.3 to 10.0% by weight, for example.

An alcoholic solvent having a boiling point that falls in the above-described range (250° C. or less; for example, 60 to 250° C.) is used as the alcoholic solvent component of the solvent mixture for the hole-injection-layer-forming ink composition 30′. Examples of such alcoholic solvents include methanol, ethanol, isopropyl alcohol, tert-butanol, n-propanol, sec-butanol, propylene glycol monomethyl ether, ethylene glycol monomethyl ether, propylene glycol monoethyl ether, ethylene glycol monoethyl ether, 2-(methoxymethoxy)ethanol, ethylene glycol monobutyl ether, ethylene glycol monoacetate, propylene glycol, dipropylene glycol monomethyl ether, diethylene glycol monomethyl ether, hexylene glycol, dipropylene glycol monoethyl ether, ethylene glycol, diethylene glycol monoethyl ether, 1,3-butylene glycol, 1-butoxyethoxy-2-propanol, diethylene glycol monobutyl ether, dipropylene glycol, 1,5-pentadiol, tripropylene glycol monomethyl ether, diethylene glycol, triethylene glycol monomethyl ether, and diethylene glycol monoacetate. These solvents may be used singly. In the case where two or more alcoholic solvents are used in combination, a solvent mixture whose boiling point, calculated from the mixture ratio, falls in the above-described range is used. For example, in the case of a 3:7 (weight basis) solvent mixture of a solvent 1 having a boiling point of A° C. and a solvent 2 having a boiling point of B° C., the boiling point of the solvent mixture calculated from the mixture ratio [(A×3/10)+(B×7/10)] has to fall in the above-described range (250° C. or less; for example, 60 to 250° C.). Individual alcoholic solvents constituting the solvent mixture may therefore have boiling points that are not in the above-described range.

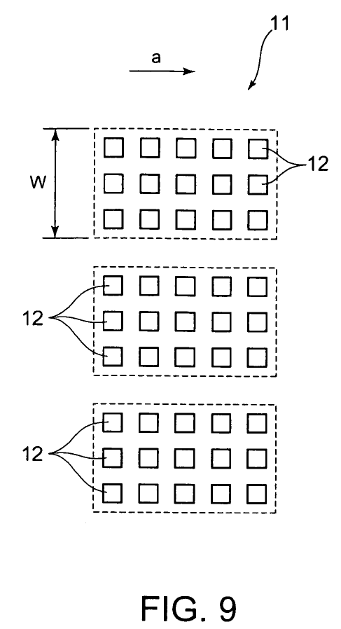

In the method for forming a light-emitting layer according to the present invention, the cells 2 (12) may be made in the gravure plate 1 (11) in such a manner that a multitude of the cells form one pattern for area color. FIG. 9 shows an example of such a gravure plate 11, and a number of cells 12 (15 cells in the embodiment shown in the figure) form one pattern (surrounded by the chain lines). In this case, the width W of one pattern may be made 200 μm or more, preferably 300 μm or more. The pattern width W is the minimum width of the pattern measured in the direction perpendicular to the direction of rotation of the gravure plate 11 (the direction indicated by the arrow a in FIG. 9). When the pattern width W is less than 200 μm, variations in the thickness of the pattern in the vicinity of its edge is 10% or more, so that such a small pattern width is unfavorable. Even when the above-described gravure plate 1 is used, it is possible to similarly form a light-emitting layer in a pattern for area color.

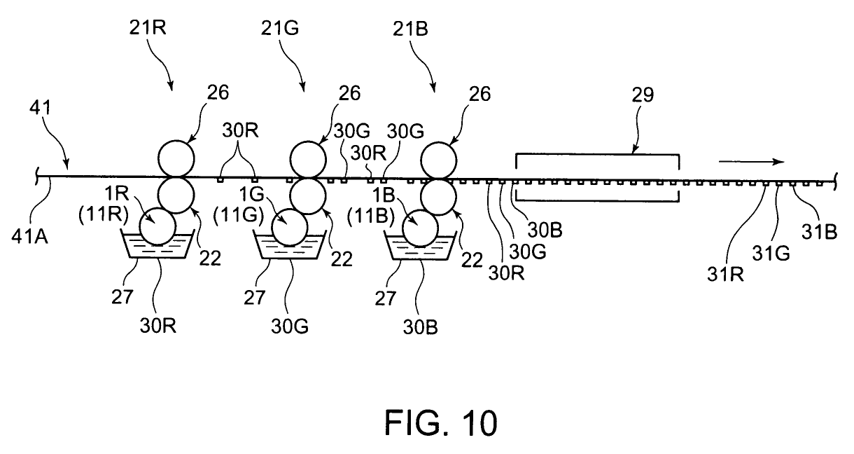

Further, in the method for forming a light-emitting layer according to the present invention, a plurality of light-emitting layers that emit light of different colors may be sequentially formed by the use of two or more sets of the gravure plate and the blanket. FIG. 10 shows this embodiment, in which a unit 21R comprising a gravure plate 1R (11R) for forming a red light-emitting layer, a blanket 22, and an impression cylinder 26, a unit 21G comprising a gravure plate 1G (11G) for forming a green light-emitting layer, a blanket 22, and an impression cylinder 26, and a unit 21B comprising a gravure plate 1B (11B) for forming a blue light-emitting layer, a blanket 22, and an impression cylinder 26 are used. Each unit 21R, 21G, or 21B is the same as the above-described printing unit 21, and an ink pan 27 for each unit 21R, 21G or 21B contains the corresponding red-light-emitting-layer-forming ink composition 30R, green-light-emitting-layer-forming ink composition 30G, or blue-light-emitting-layer-forming ink composition 30B. Passing a substrate 41 continuously through the unit 21R, the unit 21G, and the unit 21B in the order stated, the red-light-emitting-layer-forming ink composition 30R, the green-light-emitting-layer-forming ink composition 30G, and the blue-light-emitting-layer-forming ink composition 30B are sequentially transferred to the surface 41A, to be coated with light-emitting layers, of the substrate 41, and are then dried. Thus, there can be formed a red light-emitting layer 31R, a green light-emitting layer 31G, and a blue light-emitting layer 31B. The pattern of each light-emitting layer, and so forth may be freely determined, and the order in which the light-emitting layers are formed is not limited to the above-described one.

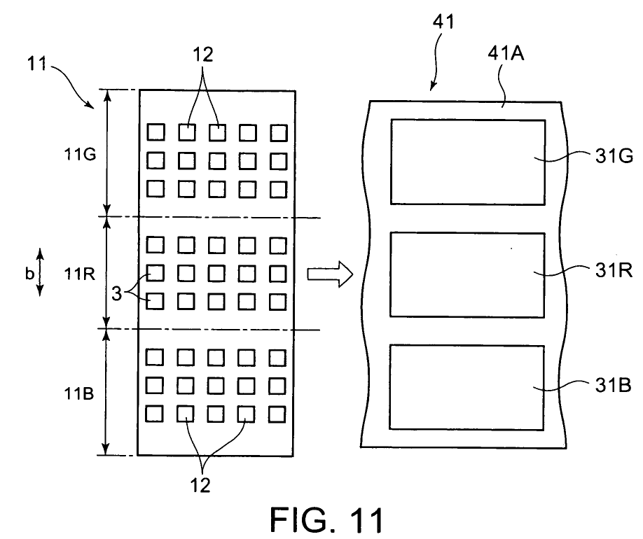

Furthermore, in the method for forming a light-emitting layer according to the present invention, a plurality of light-emitting layers that emit light of different colors may be simultaneously formed by dividing the gravure plate 1 (11) in the axial direction into a plurality of sections and supplying each section with any light-emitting-layer-forming ink composition. FIG. 11 is a view for explaining this embodiment in which the above-described gravure plate 11 is used. The gravure plate 11 is divided in the axial direction (the direction indicated by the arrow b) into three sections (11G, 11R, and 11B), each section including a number of cells 12 that forms a pattern for area color. The sections 11G, 11R, and 11B are supplied (e.g., by a dispensing method) with a green-light-emitting-layer-forming ink composition, a red-light-emitting-layer-forming ink composition, and a blue-light-emitting-layer-forming ink composition, respectively. The green-light-emitting-layer-forming ink composition, the red-light-emitting-layer-forming ink composition, and the blue-light-emitting-layer-forming ink composition are then simultaneously transferred to the surface 41A, to be coated with light-emitting layers, of a substrate 41, and are dried. Thus, there can be formed a red light-emitting layer 31R, a green light-emitting layer 31G, and a blue light-emitting layer 31B, area-color patterns. The design and the size of each pattern, the position of one pattern in relation to the other patterns, and so forth may be freely determined. Even when the aforementioned gravure plate 1 is used, it is possible to similarly form a red light-emitting layer 31R, a green light-emitting layer 31G, and a blue light-emitting layer 31B, area-color patterns.

Although the blanket 22 in the above-described embodiments rotates in the forward direction relative to the direction of rotation of the gravure plate 1 (11) and the impression cylinder 26, it may be made to rotate in the reverse direction depending on the pattern of the light-emitting layer or that of the hole-injection layer to be formed. Further, the substrate may be in sheet form, and a dispenser or the like may be used, instead of the ink pan 27, to supply the light-emitting-layer-forming ink composition 30 or the hole-injection-layer-forming ink composition 30′ to the gravure plate 1 (11).

[Organic Light-Emitting Device]

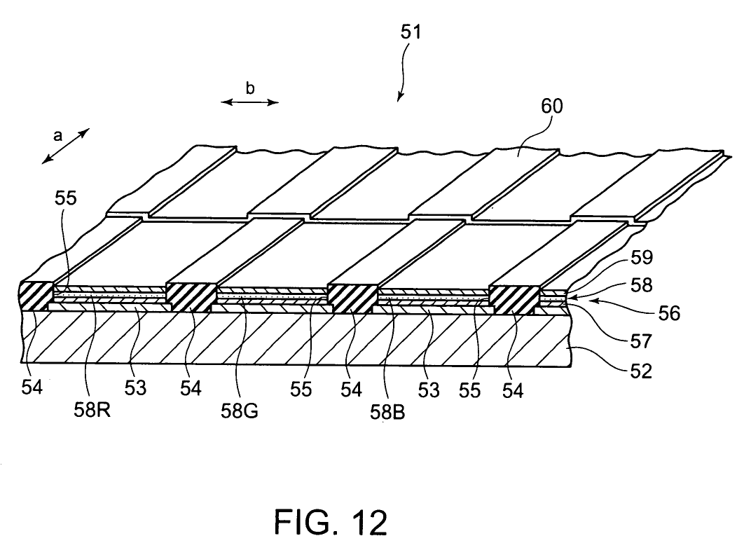

FIG. 12 is a partial sectional perspective view showing an embodiment of an organic light-emitting device of the present invention. Referring to FIG. 12, an organic light-emitting device 51 comprises a transparent substrate 52; a plurality of transparent electrode layers 53 in the shape of belts extending in the direction indicated by the arrow a, formed on the transparent substrate 52; an insulating layer 54 having openings 55 in the shape of stripes; a light-emitting device layer 56 formed to cover the transparent electrode layers 53 exposed at the bottom of the openings 55 in the shape of stripes that exist on the transparent electrode layers 53; and a plurality of electrode layers 60 in the shape of belts extending in the direction indicated by the arrow b, formed on the light-emitting device layer 56 in such a manner that they cross the transparent electrode layers 53 at right angles.

The openings 55 in the above-described insulating layer 54 are in the shape of stripes extending in the direction indicated by the arrow a, and are present on the transparent electrode layers 53.

The light-emitting device layer 56 is composed of a hole-injection layer 57, a light-emitting layer 58, and an electron-injection layer 59 that are formed to cover the transparent electrode layers exposed at the bottom of the openings 55. In the embodiment shown in the figure, the light-emitting layer 58 consists of a belt-shaped red light-emitting layer 58R, a belt-shaped green light-emitting layer 58G, and a belt-shaped blue light-emitting layer 58B that are repeatedly arranged, in the order mentioned, in the direction indicated by the arrow b. The hole-injection layer 57, the light-emitting layer 58, and the electron-injection layer 59 may also be formed in such a manner that they overlap with the insulating layer 54 at the rims of the openings 55.

Such an organic light-emitting device 51 is of passive matrix type that intersections of the belt-shaped transparent electrode layers 53 and the belt-shaped electrode layers function as light-emitting regions, and the hole-injection layer 57 and the light-emitting layer 58 of the light-emitting device layer 56 are formed by the method for forming a hole-injection layer according to the present invention and the method for forming a light-emitting layer according to the present invention, respectively. Therefore, the hole-injection layer 57 has a thickness of 50 nm or more, and the light-emitting layer 58 has a thickness of 70 nm or more. Consequently, the luminance and the emission efficiency of the light-emitting device layer 56 at the time of emission of light are high, which leads to good display performance. Further, even if the light-emitting device layer 56 is formed in such a manner that it overlaps with the insulating layer 54 at the rims of the openings 55, a short circuit is not formed between the transparent electrode layer 53 and the electrode layer 60 that are present in such positions that the light-emitting device layer 56 exists between the two layers, which leads to higher reliability.

The components of the organic light-emitting device 51 of the present invention will be described below.

The transparent substrate 52, a component of the organic light-emitting device 51, generally forms the observer-side surface of the device and has transparency to such a degree that observers can easily recognize the light emitted from the light-emitting layer 58. As will be described later, when the emission direction is made opposite, an opaque substrate may be used in place of the transparent substrate 52.

Glass materials, resin materials, or composites of these materials such as glass plates covered with protective plastic films or layers are used for the transparent substrate 52 (including the alternative opaque substrate).

Examples of the above-described resin materials and protective plastics include fluoroplastics, polyethylene, polypropylene, polyvinyl chloride, polyvinyl fluoride, polystyrene, ABS resins, polyamide, polyacetal, polyester, polycarbonate, modified polyphenylene ether, polysulfone, polyallylate, polyether imide, polyamide imide, polyimide, polyphenylene sulfide, liquid crystalline polyester, polyethylene terephthalate, polybutylene terephthalate, polyethylene naphthalate, polyoxymethylene, polyether sulfone, polyether ether ketone, polyacrylate, acrylonitrile-styrene resins, phenol resins, urea resins, melamine resins, unsaturated polyester resins, epoxy resins, polyurethane, silicone resins, and amorphous polyolefins. Resin materials other than the above-described ones can also be used if they are high-molecular-weight materials useful for organic light-emitting devices.

The thickness of the transparent substrate 52 is usually about 50 μm to 1.1 mm.

Although depending on the use to which the light-emitting device will be put, it is more preferable to use, for the transparent substrate 52, a transparent material excellent in barrier properties to water vapor or to gases such as oxygen. Alternatively, a barrier layer effective for water vapor or gases such as oxygen may be formed on the transparent substrate 52. Such a barrier layer may be a layer of an inorganic oxide, such as silicon, aluminum, or titanium oxide, formed by sputtering or physical deposition such as vacuum deposition.

In the embodiment shown in the figure, the transparent electrode layers 53, a component of the organic light-emitting device 51, are anodes, and are formed next to the hole-injection layers 57 so that positive electric charges (holes) are injected into the light-emitting layer 58. The transparent electrode layers 53 may also be cathodes. In this case, the hole-injection layers 57 and the electron-injection layers 59, constituent layers of the light-emitting device layer 56, are reversed in position.

Any material can be used for the transparent electrode layers 53 as long as it is useful for conventional organic light-emitting devices, and metals, alloys, mixtures of metals and/or alloys, and the like may be used. Examples of materials useful for the transparent electrode layers 53 include materials for thin film electrodes, such as indium tin oxide (ITO), indium oxide, indium zinc oxide (IZO), zinc oxide, stannic oxide, and gold. Of these materials, ITO, IZO, indium oxide, and gold, which are transparent or semi-transparent materials having great work functions (4 eV or more), are preferably used for the transparent electrode layers 53 so that hole injection easily occurs.

It is preferred that the transparent electrode layers 53 have, as a sheet, an electrical resistance of several hundreds Ω/□ or less. The thickness of the transparent electrode layers 53 may be approximately 0.005 to 1 μm, for example, although it varies depending on the material to be used for the transparent electrode layers 53.

The transparent electrode layers 53 are formed in the desired pattern that covers the whole area including the terminal areas, the edge portions, and the pixel area, the center portion. Such patterned transparent electrode layers 53 are obtained by forming pattern-wise a film using a metal mask, or forming a film on the entire surface of the transparent substrate, by sputtering, vacuum deposition, or the like and etching the film masked with a photosensitive resist.

The insulating layer 54, a component of the organic light-emitting device 51, has openings 55 in the shape of stripes that are situated on the transparent electrode layers 53. The insulating layer 54 may be formed in the following manner, for example: a photosensitive resin material is applied to fully cover the transparent electrode layers 53, and the film formed is subjected to pattern-wise exposure to light and development. Alternatively, a thermosetting resin material may be used to form the insulating layer 54. The non-opening portions of the insulating layer 54 do not emit light. Although the thickness of the insulating layer 54 may be determined with consideration for the inherent insulation resistance of the resin to be used to form the insulating layer 54, it may be made approximately 0.05 to 5.0 μm, for example. A black matrix made from a mixture of the above-described resin material and one type of, or two or more types of, light-shielding fine particles selected from carbon black, and titanium black pigments such as titanium nitride, titanium oxide, and titanic acid nitride may also be used as the insulating layer 54.

The form of such an insulating layer 54 is not limited to the above-described one.

Although the light-emitting device layer 56, a component of the organic light-emitting device 51 in the embodiment shown in the figure, has a structure that the hole-injection layer 57, the light-emitting layer 58, and the electron-injection layer 59 are laminated in the order mentioned, the hole-injection layer 57 being on the transparent electrode layer 53 side, it may have other structures such as a structure that the hole-injection layer 57 and the light-emitting layer 58 constitute the light-emitting device layer 56, a structure that the light-emitting layer 58 and the electron-injection layer 59 constitute the light-emitting device layer 56, a structure that a hole-transport layer is present between the hole-injection layer 57 and the light-emitting layer 58, and a structure that an electron-transport layer is present between the light-emitting layer 58 and the electron-injection layer 59.

Further, for the purpose of adjusting the wavelength of light to be emitted or of improving emission efficiency, the above-described layers may be doped with proper materials.

In the embodiment shown in the figure, the light-emitting layer 58 in the light-emitting device layer 56 consists of the red light-emitting layer 58R, the green light-emitting layer 58G, and the blue light-emitting layer 58B. However, depending on the use to which the organic light-emitting device will be put, a light-emitting layer that emits light of the desired color (e.g., yellow, turquoise, or orange) may be singly used, or light-emitting layers that emit light of the two or more desired colors other than red, green and blue may be used in combination.

The hole-injection materials and the organic light-emitting materials that have been enumerated in the above description of the method for forming a hole-injection layer according to the present invention and the description of the method for forming a light-emitting layer according to the present invention, respectively, can be used as hole-injection materials for the hole-injection layer 57 in the light-emitting device layer 56, and as organic light-emitting materials for the light-emitting layer 58 in the light-emitting device layer 56, respectively.

The doping materials, hole-transport materials, electron-injection materials, etc. for the constituent layers of the light-emitting layer 56 may be any of the following inorganic or organic materials. The thickness of each constituent layer of the light-emitting layer 56 has no limits, and it may be approximately 10 to 1000 nm, for example.

(Doping Materials)

Examples of dopants useful herein include perylene derivatives, coumarin derivatives, rubrene derivatives, quinacridone derivatives, squalium derivatives, porphyrin derivatives, styryl dyes, tetracene derivatives, pyrazoline derivatives, decacyclene, and phenoxazone.

(Hole-Transport Materials)

Examples of hole-transport materials useful herein include oxadiazole compounds, oxazole compounds, triazole compounds, thiazole compounds, triphenylmethane compounds, styryl compounds, pyrazoline compounds, hydrazone compounds, aromatic amine compounds, carbazole compounds, polyvinyl carbazole compounds, stilbene compounds, enamine compounds, azine compounds, triphenylamine compounds, butadiene compounds, polycyclic aromatic compounds, and stilbene dimers.

Hole-transport materials also include π conjugated polymers such as polyacetylene, polydiacetylene, poly(p-phenylene), poly(p-phenylene sulfide), poly(p-phenylene oxide), poly(1,6-heptadiene), poly(p-phenylenevinylene), poly(2,5-thienylene), poly(2,5-pyrrole), poly(m-phenylene sulfide), and poly(4,4′-biphenylene).

Hole-transport materials also include high-molecular-weight charge-transfer complexes such as polystyrene.AgClO₄, polyvinyl-naphthalene.TCNE, polyvinylnaphthalene.P-CA, polyvinyinaphthalene.DDQ, polyvinylmesitylene.TCNE, polynaphthacetylene.TCNE, polyvinylanthracene.Br₂, polyvinylanthracene.I₂, polyvinylanthracene.TNB, polydimethylaminostyrene.CA, polyvinylimidazole.CQ, poly-p-phenylene.I₂, poly-1-vinylpyridine.I₂, poly-4-vinylpyridine.I₂, poly-p-1-phenylene.I₂, and polyvinylpyridium.TCNQ. Hole-transport materials also include low-molecular-weight charge-transfer complexes such as TCNQ-TTF, and polymeric metal complexes such as poly(copper phthalocyanine).

Hole-transport materials having low ionization potential are preferred, and, specifically, butadiene compounds, enamine compounds, hydrazone compounds, and triphenylamine compounds are preferred.

(Electron-Injection Materials)

Examples of electron-injection materials useful herein include calcium, barium, lithium aluminum, lithium fluoride, strontium, magnesium oxide, magnesium fluoride, strontium fluoride, calcium fluoride, barium fluoride, aluminum oxide, strontium oxide, calcium oxide, polymethyl methacrylate, polystyrene sodium sulfonate, nitro-substituted fluorene derivatives, anthraquinone dimethane derivatives, diphenylquinone derivatives, thiopyran dioxide derivatives, heterocyclic tetracarbonic anhydrides such as naphthalene perylene, carbodiimide, fluorenylidene methane derivatives, anthraquinodimethane derivatives, anthrone derivatives, oxadiazole derivatives, thiazole derivatives obtained by substituting oxygen atom on the oxadiazole ring in the above-described oxadiazole derivatives with sulfur atom, quinoxaline derivatives having quinoxaline ring known as an electron-attractive group, metal complexes of 8-quinolinol derivatives such as tris(8-quinolinol)aluminum, phthalocyanine, metal phthalocyanine, and distyrylpyrazine derivatives.

The hole-injection layer 57 and the light-emitting layer 58, constituent layers of the light-emitting device layer 56, are formed by the methods of the present invention described above. Alternatively, the two layers 57, 58 may be formed in the following manner: a film for the light-emitting layer is formed within 1 minute after forming a film for the hole-injection layer, and these two films are simultaneously dried at a temperature of 100 to 200° C.

The electron-injection layer 59 may be formed by vacuum deposition or the like, using a mask with an opening that corresponds to an image-display area (a mask for preventing deposition of a film on an electrode terminal, the peripheral part of the transparent electrode layers 53). Such a printing method as screen process printing may be employed as well to form the electron-injection layer 59.

In the embodiment shown in the figure, the electrode layers 60, a component of the organic light-emitting device 51, are cathodes, and are formed next to the electron-injection layer 59 so that negative charges (electrons) are injected into the light-emitting layer 58. The electrode layers 60 may also be anodes. In this case, the hole-injection layer 57 and the electron-injection layer 59, constituent layers of the light-emitting device layer 56, are reversed in position.

Any material can be used for the electrode layers 60 as long as it is useful for conventional organic light-emitting devices. Materials for thin film electrodes that are useful for the above-described transparent electrode layers 53, such as indium tin oxide (ITO), indium oxide, indium zinc oxide (IZO), zinc oxide, stannic oxide, and gold, and, in addition, magnesium alloys (e.g., MgAg, etc.), aluminum, aluminum alloys (AlLi, AlCa, AIMg, etc.), silver, and so forth are useful for the electrode layers 60. Of these materials, magnesium alloys, aluminum, silver, and the like, which have small work functions (below 4 eV), are preferably used for the electrode layers so that electron injection easily occurs. It is preferred that the electrode layers 60 have, as a sheet, an electrical resistance of several hundreds Ω/□ or less, so that the thickness of the electrode layers 60 may be made approximately 0.005 to 0.5 μm, for example.

The above-described electrode layers 60 can be formed by making the above-described electrode material into a patterned film by sputtering, vacuum deposition, or the like, using a mask.

In the above-described organic light-emitting device 51, if a transparent material is used to form the electrode layers 60, it is possible to make the emission direction opposite to the above-described one. In this case, the substrate 52 is not needed to be transparent, and opaque electrode layers may be formed in place of the transparent electrode layers 53.

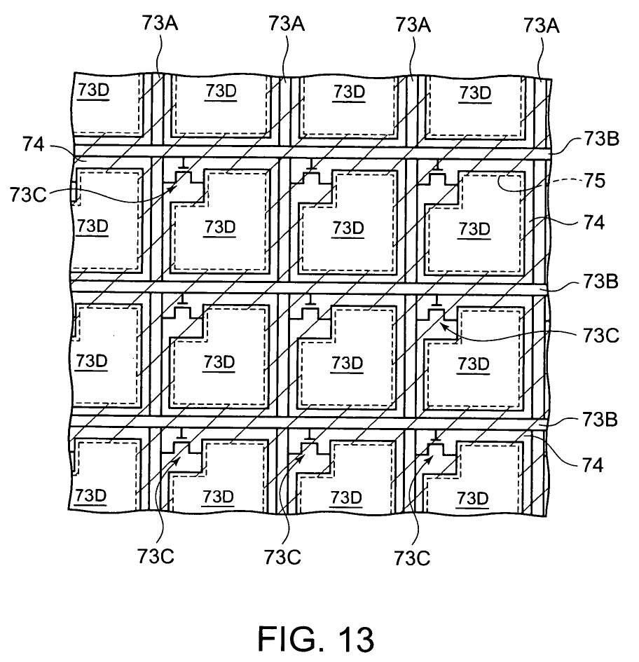

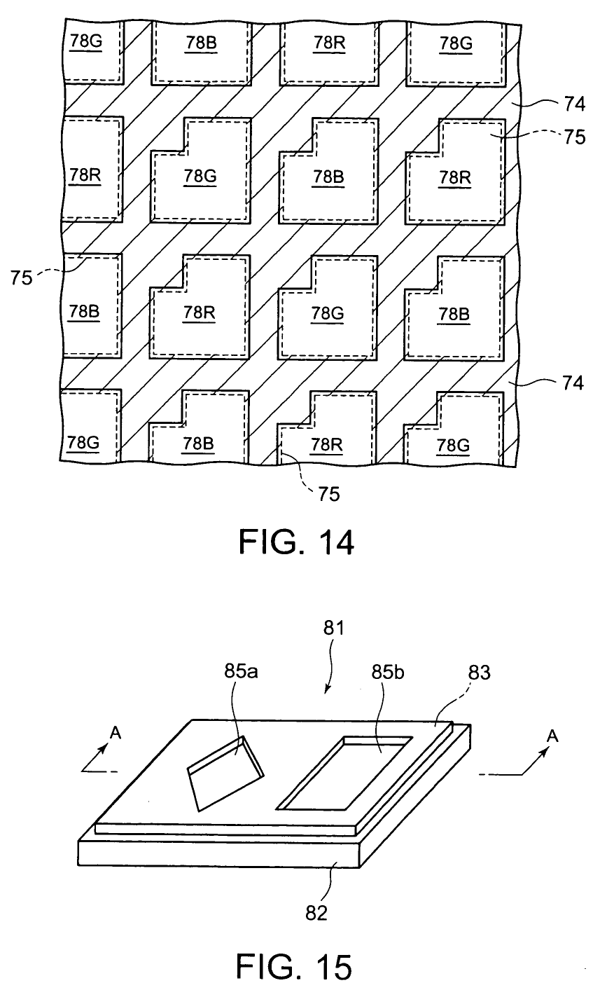

Alternatively, the organic light-emitting device of the present invention may be of active matrix type. FIGS. 13 and 14 are views for explaining an active-matrix-type organic light-emitting device of the present invention. FIG. 13 is a view showing electrode-wiring patterns. An electrode-wiring pattern 73 formed on a transparent substrate (not shown in the figure) consists of a signal conductor 73A, a scanning line 73B, a TFT (thin film transistor) 73C, and a transparent electrode (pixel electrode) layer 73D. An insulating layer 74 (the portion depicted with oblique lines in FIG. 13) is formed so that it covers the electrode-wiring patterns 73. This insulating layer 74 has openings 75 on the transparent electrode layers 73D. Further, a light-emitting device layer (not shown in the figure) is formed on the insulating layer 74 so that it covers the transparent electrode layers 73D exposed at the bottom of the openings 75, and an electrode (common electrode) layer (not shown in the figure) is formed on this light-emitting device layer.

The above-described light-emitting device layer may be composed of a hole-injection layer formed to cover the insulating layer 74 and the transparent electrode layers 73D exposed at the bottom of the openings 75, a plurality of light-emitting layers formed in the openings 75 so that they cover the transparent electrode layers 73D (hole-injection layers) exposed at the bottom of the openings 75, and an electron-injection layer formed to cover these layers. FIG. 14 is a view showing the relationship between the openings 75 in the insulating layer 74 and the light-emitting layer. In FIG. 14, the light-emitting layer consists of a red light-emitting layer 78R, a green light-emitting layer 78G, and a blue light-emitting layer 78B that are in the desired patterns, the size of each light-emitting layer greater than that of each opening 75.

The hole-injection layer and the light-emitting layer (the red light-emitting layer 78R, the green light-emitting layer 78G, and the blue light-emitting layer 78B) of the above-described active-matrix-type organic light-emitting device of the present invention are also formed by the method for forming a hole-injection layer according to the present invention and a method for forming a light-emitting layer according to the present invention, respectively. Therefore, the hole-injection layer has a thickness of 50 nm or more, and the light-emitting layer (the red light-emitting layer 78R, the green light-emitting layer 78G, and the blue light-emitting layer 78B) has a thickness of 70 nm or more. Consequently, the luminance and the emission efficiency of the light-emitting device layer at the time of emission of light are high, which leads to good display performance. Further, even when the light-emitting device layer is formed in such a manner that it overlaps with the insulating layer 74 at the rims of the openings 75, a short circuit is not formed between the transparent electrode layer 73D and the electrode layer (not shown in the figure) that are present in such positions that the light-emitting device layer exists between the two layers, which leads to higher reliability.

As in the aforementioned embodiment, the above-described light-emitting device layer may have a structure that the hole-injection layer and the light-emitting layer constitute the light-emitting device layer, a structure that the light-emitting layer and the electron-injection layer constitute the light-emitting device layer, a structure that a hole-transport layer is present between the hole-injection layer and the light-emitting layer, or a structure that an electron-transport layer is present between the light-emitting layer and the electron-injection layer.

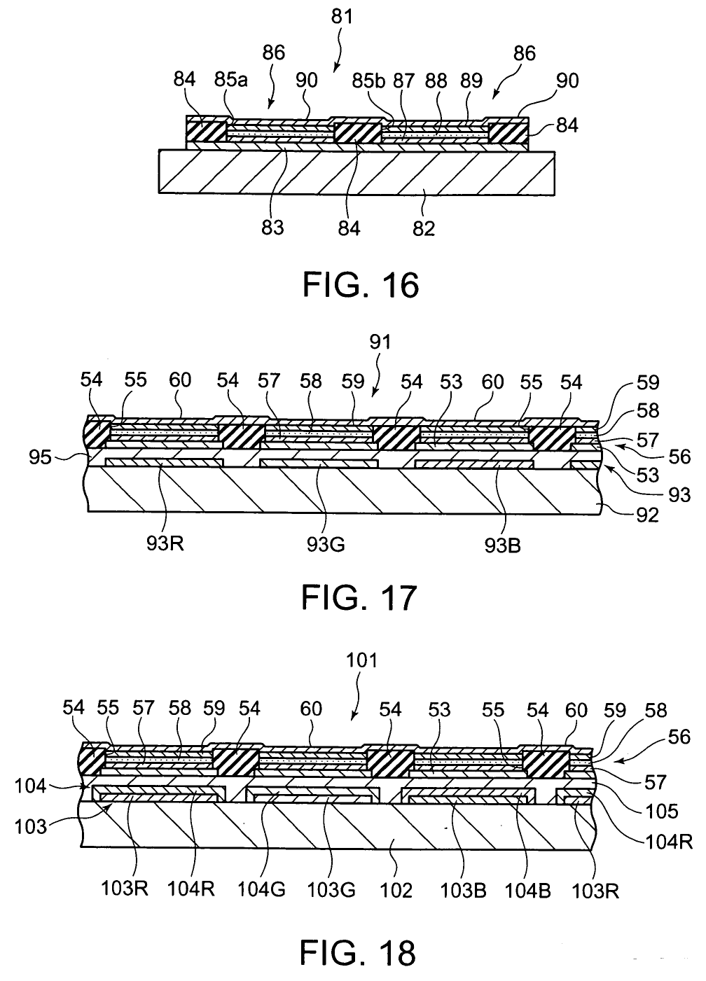

FIG. 15 is a partial perspective view showing another embodiment of an organic light-emitting device of the present invention, and FIG. 16 is a sectional view of the organic light-emitting device shown in FIG. 15, taken along line A-A of FIG. 15. In FIGS. 15 and 16, an organic light-emitting device 81 comprises a transparent substrate 82, a rectangular transparent electrode layer 83 formed on the transparent substrate 82, an insulating layer 84 having both a rhombic opening 85a and a rectangular opening 85B, a light-emitting device layer 86 formed to cover the transparent electrode layer 83 exposed at the bottom of the openings 85a, 85b, and an electrode layer 90 formed to cover the light-emitting device layer 86.

The above-described light-emitting device layer 86 is a laminate of a hole-injection layer 87, a light-emitting layer 88, and an electron-injection layer 89. The light-emitting device layer 86 may also be formed in such a manner that it overlaps with the insulating layer 84 at the rims of the openings 85a, 85b.

Such an organic light-emitting device 81 achieves area-color display, where the part including the openings 85a, 85b is a display area. For example, it is possible to use the organic light-emitting device 81 as an organic light-emitting poster by making the maximum width of the openings 85a, 85b 10 mm or greater. The hole-injection layer 87 and the light-emitting layer 88, components of the organic light-emitting device 81, are formed by the method for forming a hole-injection layer according to the present invention and the method for forming a light-emitting layer according to the present invention, respectively. Therefore, the hole-injection layer 87 has a thickness of 50 nm or more, and the light-emitting layer 88 has a thickness of 70 nm or more. Consequently, the luminance and the emission efficiency of the light-emitting device layer 86 at the time of emission of light are high, which leads to good display performance. Further, even when the light-emitting device layer 86 is formed in such a manner that it overlaps with the insulating layer 84 at the rims of the openings 85a, 85b, a short circuit is not formed between the transparent electrode layer 83 and the electrode layer 90 that are present in such positions that the light-emitting device layer 86 exists between the two layers, which leads to higher reliability.

The light-emitting layer existing on the opening 85a and that existing on the opening 85b may emit light of different colors. Moreover, the electrode layer 90 on the opening 85a and that on the opening 85b may be made electrically independent so that the light-emitting layers emit light independently.

As in the aforementioned embodiment, the above-described light-emitting device layer 86 may have a structure that the hole-injection layer and the light-emitting layer constitute the light-emitting device layer, a structure that the light-emitting layer and the electron-injection layer constitute the light-emitting device layer, a structure that a hole-transport layer is present between the hole-injection layer and the light-emitting layer, or a structure that an electron-transport layer is present between the light-emitting layer and the electron-injection layer.

FIG. 17 is a partial sectional view showing a further embodiment of an organic light-emitting device of the present invention. An organic light-emitting device 91 shown in FIG. 17 comprises a transparent substrate 92; a color filter layer 93 formed on the transparent substrate 92, consisting of a belt-shaped red-colored layer 93R, a belt-shaped green-colored layer 93G, and a belt-shaped blue-colored layer 93B; a transparent smoothening layer 95 formed to cover the color filter layer 93; a plurality of belt-shaped transparent electrode layers 53 formed on the transparent smoothening layer 95 in the same manner as that in which the transparent electrode layers in the above-described organic light-emitting device 51 are formed; an insulating layer 54 with openings 55 formed on the transparent electrode layers 53 so that the openings 55 in the shape of stripes are present on the transparent electrode layers 53; a light-emitting device layer 56 formed to cover the transparent electrode layers 53 exposed at the bottom of the openings 55; and a plurality of belt-shaped electrode layers 60 formed on the light-emitting device layer 56 so that they cross the transparent electrode layers 53 at right angles.

A plurality of the belt-shaped transparent electrode layers 53 described above are positioned on the belt-shaped red-colored layer 93R, green-colored layer 93G, and blue-colored layer 93B. The light-emitting device layer 56 consists of a hole-injection layer 57 formed to cover the transparent electrode layers 53 exposed at the bottom of the openings 55, a plurality of light-emitting layers 58 formed in the openings 55 to cover the transparent electrode layers 53 (hole-injection layers 57) present at the bottom of the openings 55, and an electron-injection layer 59 formed to cover these layers. In the embodiment shown in the figure, the light-emitting layers 58 are belt-shaped layers that emit white light. The light-emitting device layer 56 may also be formed in such a manner that it overlaps with the insulating 54 at the rims of the openings 55.

Such an organic light-emitting device 91 is the same as the above-described organic light-emitting device 51, except that the organic light-emitting device 91 comprises the color filter layer 93 and the transparent smoothening layer 95 and that the light-emitting layers 58 emit white light. Therefore, in the figure showing the organic light-emitting device 91 and the figure showing the organic light-emitting device 51, like reference numerals designate like parts, and such parts of the light-emitting device 91 are not explained any more. As in the aforementioned embodiment, the above-described light-emitting device layer 56 may have a structure that the hole-injection layer and the light-emitting layer constitute the light-emitting device layer, a structure that the light-emitting layer and the electron-injection layer constitute the light-emitting device layer, a structure that a hole-transport layer is present between the hole-injection layer and the light-emitting layer, or a structure that an electron-transport layer is present between the light-emitting layer and the electron-injection layer.

The above-described color filter layer 93 is for correcting the color of light emerging from the light-emitting device layer 56 and for increasing color purity. Materials for the red-colored layer 93R, the green-colored layer 93G, and the blue-colored layer 93B, constituent layers of the color filter layer 93, can be properly selected with consideration for the light emission properties of the light-emitting device layer 56. For example, a pigment-dispersed composition containing a pigment, a pigment dispersant, a binder resin, a reactive compound, and a solvent may be used to form each colored layer. The thickness of such a color filter layer 93 may be determined with consideration for the material for each colored layer, the light emission properties of the organic EL device layer, and so forth, and it can be made about 1 to 3 μm, for example.

The transparent smoothening layer 95 has the smoothening action, and, when irregularities (surface roughness) are present due to the presence of the color filter layer 93, the smoothening layer 95 smoothens the irregularities, thereby preventing the light-emitting device layer 56 from becoming non-uniform in thickness. A transparent (transmittance for visible light: 50% or more) resin can be used to form the transparent smoothening layer 95. Specifically, photosetting or thermosetting acrylate or methacrylate resins having reactive vinyl groups are useful for the transparent smoothening layer 95. Examples of the transparent resin further include polymethyl methacrylate, polyacrylate, polycarbonate, polyvinyl alcohol, polyvinyl pyrrolidone, hydroxyethyl cellulose, carboxymethyl cellulose, polyvinyl chloride resins, melamine resins, phenol resins, alkyd resins, epoxy resins, polyurethane resins, polyester resins, maleic acid resins, and polyamide resins.

The thickness of such a transparent smoothening layer 95 can be determined with consideration for the material to be used so that the smoothening layer 95 reveals its smoothening action. For example, the thickness of the transparent smoothening layer 95 is approximately from 1 to 5 μm.

FIG. 18 is a partial sectional view showing a still further embodiment of an organic light-emitting device of the present invention. An organic light-emitting device 101 shown in FIG. 18 comprises a transparent substrate 102; a color filter layer 103 formed on the transparent substrate 102, consisting of a belt-shaped red-colored layer 103R, a belt-shaped green-colored layer 103G, and a belt-shaped blue-colored layer 103B; a color-changing phosphor layer 104 consisting of a belt-shaped red color-changing phosphor layer 104R (a layer for changing blue light into red fluorescence), a belt-shaped green color-changing phosphor layer 104G (a layer for changing blue light into green fluorescence), and a belt-shaped blue dummy layer 104B (a layer for transmitting blue light as it is) that are formed to cover the red-colored layer 103R, the green-colored layer 103G, and the blue-colored layer 103B, constituent layers of the color filter layer 103, respectively; a transparent smoothening layer 105 formed to cover these layers; a plurality of belt-shaped transparent electrode layers 53 formed on the transparent smoothening layer 105 in the same manner as that in which the transparent electrode layers in the above-described organic light-emitting device 51 are formed; an insulating layer 54 with openings 55 formed on the transparent electrode layers 53 so that the openings 55 in the shape of stripes are positioned on the transparent electrode layers 53; light-emitting device layers 56 formed to cover the transparent electrode layers 53 exposed at the bottom of the openings 55; and a plurality of belt-shaped electrode layers 60 formed on the light-emitting device layers 56 so that they cross the transparent electrode layers 53 at right angles.

A plurality of the belt-shaped transparent electrode layers 53 described above are positioned on the belt-shaped red color-changing phosphor layer 104R, the belt-shaped green color-changing phosphor layer 104G, and the belt-shaped blue dummy layer 104B. The light-emitting device layer 56 consists of a hole-injection layer 57, a light-emitting layer 58, and an electron-injection layer 59 that are formed to cover the transparent electrode layer 53 exposed at the bottom of the opening 55. In the embodiment shown in the figure, the light-emitting layers 58 are belt-shaped layers that emit blue light. The light-emitting device layers 56 may also be formed in such a manner that they overlap with the insulating layer 54 at the rims of the openings 55.

Such an organic light-emitting device 101 is the same as the above-described organic light-emitting device 51, except that the organic light-emitting device 101 comprises the color filter layer 103, the color-changing phosphor layer 104, and the transparent smoothening layer 105 and that the light-emitting layers 58 emit blue light. Therefore, in the figure showing the organic light-emitting device 101 and the figure showing the organic light-emitting device 51, like reference numerals designate like parts, and such parts of the light-emitting device 101 are not explained any more. Further, the color filter layer 103 and the transparent smoothening layer 105 are the same as the above-described color filter layer 93 and transparent smoothening layer 95, respectively, so that explanation of these layers is omitted here. As in the aforementioned embodiment, the above-described light-emitting device layer 56 may have a structure that the hole-injection layer and the light-emitting layer constitute the light-emitting device layer, a structure that the light-emitting layer and the electron-injection layer constitute the light-emitting device layer, a structure that a hole-transport layer is present between the hole-injection layer and the light-emitting layer, or a structure that an electron-transport layer is present between the light-emitting layer and the electron-injection layer.

The above-described red color-changing phosphor layer 104R and green color-changing phosphor layer 104G are layers of fluorescent coloring agents, or layers of resins containing fluorescent coloring agents. Examples of fluorescent coloring agents useful for the red color-changing phosphor layer 104R for changing blue light into red fluorescence include cyanine dyes such as 4-dicyanomethylene-2-methyl-6-(p-dimethylamino-styryl)-4H-pyran, pyridine dyes such as 1-ethyl-2-[4-(p-dimethylamino-phenyl)-1,3-butadienyl]-pyridium-perchlorate, rhodamine dyes such as rhodamine B and rhodamine 6G, and oxazine dyes. Examples of fluorescent coloring agents useful for the green color-changing phosphor layer 104G for changing blue light into green fluorescence include coumarin dyes such as 2,3,5,6-1H,4H-tetrahydro-8-trifluoromethyl-quinolizino(9,9a,1-gh)coumarin, 3-(2′-benzothiazolyl)-7-diethylamino-coumarin, and 3-(2′-benzimidazolyl)-7-N,N-diethylaminocoumarin, coumarin-type dyes such as Basic Yellow 51, and naphthalimide dyes such as Solvent Yellow 11 and Solvent Yellow 116. A variety of other dyes including direct dyes, acid dyes, basic dyes, and disperse dyes may be used as well if they are fluorescent. The above-described fluorescent coloring agents are used singly. Alternatively, two or more of the above-described fluorescent coloring agents may be used in combination. In the case where the red color-changing phosphor layer 104R and the green color-changing phosphor layer 104G are layers of resins containing fluorescent coloring agents, the fluorescent coloring agent contents of the resins may be properly determined with consideration for the fluorescent coloring agents to be used, the thickness of the color-changing phosphor layer, and so forth. For example, the fluorescent coloring agent may be used in an amount of approximately 0.1 to 1 part by weight for 100 parts by weight of the resin.

The blue dummy layer 104B is for transmitting blue light emitted from the light-emitting device layer 56, as it is, to the color filter layer 103, and it may be a transparent resin layer having a thickness nearly equal to the thickness of the red color-changing phosphor layer 104R or that of the green color-changing phosphor layer 104G.

In the case where the red color-changing phosphor layer 104R and the green color-changing phosphor layer 104G are layers of resins containing fluorescent coloring agents, transparent (transmission for visible light: 50% or more) resins such as polymethyl methacrylate, polyacrylate, polycarbonate, polyvinyl alcohol, polyvinyl pyrrolidone, hydroxyethyl cellulose, carboxymethyl cellulose, polyvinyl chloride resins, melamine resins, phenol resins, alkyd resins, epoxy resins, polyurethane resins, polyester resins, maleic acid resins, and polyamide resins can be used as the resins. Further, in the case where the color-changing phosphor layer 104 is photolithographically patterned, photo-setting resist resins having reactive vinyl groups, such as acrylic resins, methacrylic resins, polyvinyl cinnamate resins, and cyclic rubber resins, are useful. These resins can be used for the above-described blue dummy layer 104B as well.

When fluorescent coloring agents are used singly to form the red color-changing phosphor layer 104R and the green color-changing phosphor layer 104G, constituent layers of the color-changing phosphor layer 104, such a method as vacuum deposition or sputtering using the desired mask for patterning may be employed to form these layers in the shape of belts. When resins containing fluorescent coloring agents are used to form these layers 104R, 104G, the following method may be employed: a method that a film formed by applying, by such a method as spin coating, roll coating, or cast coating, a coating liquid prepared by dispersing or solubilizing a fluorescent coloring agent and a resin is photolithographically patterned; or a method that a patterned film is formed by screen process printing or the like using the above coating liquid. The following method may be employed to form the blue dummy layer 104B: a method that a film formed by applying the desired photosensitive resin coating by such a method as spin coating, roll coating, or cast coating is photolithographically patterned; or a method that a patterned film is formed by screen process printing or the like using the desired resin coating liquid.

The color-changing phosphor layer 104 described above should have such a thickness that the red color-changing phosphor layer 104R and the green color-changing phosphor layer 104G satisfactorily absorb blue light emitted from the light-emitting device layer 56 and generate fluorescence. The thickness of the color-changing phosphor layer 104 may be properly determined with consideration for the fluorescent coloring agents to be used, the concentrations of the fluorescent coloring agents, and so forth, and it is from about 10 to 20 μm, for example. The thickness of the red color-changing phosphor layer 104R and that of the green color-changing phosphor layer 104G may be different from each other.

Examples of organic fluorescent materials that emit blue light include fluorescent whitening agents such as benzothiazole compounds, benzoimidazole compounds, and benzoxazole compounds, metal-chelated oxynoide compounds, styryl benzene compounds, distyryl pyrazine derivatives, and aromatic dimethylidyne compounds.

Specific examples of the fluorescent whitening agents include benzothiazole compounds such as 2-2′-(p-phenylenedivinylene)-bisbenzothiazole; benzoimidazole compounds such as 2-[2-[4-(2-benzoimidazolyl)phenyl]vinyl]benzoimidazole, and 2-[2-(4-carboxy-phenyl)vinyl]benzoimidazole; and benzoxazole compounds such as 2,5-bis(5,7-di-t-pentyl-2-benzoxazolyl)-1,3,4-thiadiazole, 4,4′-bis(5,7-t-pentyl-2-benzoxazolyl)stilbene, and 2-[2-(4-chlorophenyl)vinyl]naphtho[1,2-d]oxazole.

Examples of the metal-chelated oxynoide compounds include 8-hydroxyquinoline metal complexes such as tris(8-quinolinol)aluminum, bis(8-quinolinol)magnesium, and bis(benzo[f]-8-quinolinol)zinc, and dilithium epintridione.

Examples of the styryl benzene compounds include 1,4-bis(2-methylstyryl)benzene, 1,4-bis(3-methylstyryl)benzene, 1,4-bis(4-methylstyryl)benzene, distyryl benzene, 1,4-bis(2-ethylstyryl)benzene, 1,4-bis(3-ethylstyryl)benzene, 1,4-bis(2-methylstyryl)-2-methylbenzene, and 1,4-bis(2-methylstyryl)-2-ethylbenzene.

Examples of the distyryl pyrazine derivatives include 2,5-bis(4-methylstyryl)pyrazine, 2,5-bis(4-ethylstyryl)pyrazine, 2,5-bis[2-(1-naphthyl)vinyl]pyrazine, 2,5-bis(4-methoxystyryl)pyrazine, 2,5-bis[2-(4-biphenyl)vinyl]pyrazine, and 2,5-bis[2-(1-pyrenyl)vinyl]pyrazine.

Examples of the aromatic dimethylidyne compounds include 1,4-phenylenedimethylidyne, 4,4-phenylenedimethylidyne, 2,5-xylene-dimethylidyne, 2,6-naphthylenedimethylidyne, 1,4-biphenylene-dimethylidyne, 1,4-p-terephenylenedimethylidyne, 9,10-anthracene-diyldimethylidyne, 4,4′-bis(2,2-di-t-butylphenylvinyl)biphenyl, and 4,4′-bis(2,2-diphenylvinyl)biphenyl, and derivatives thereof.

Furthermore, compounds represented by the general formula (Rs-Q) 2-AL-O-L (wherein AL is a hydrocarbon having 6 to 24 carbon atoms, containing benzene ring, O-L is a phenylate ligand, Q is a substituted 8-quinolilate ligand, and Rs is an 8-quinolilate substituent selected so that it causes steric hindrance to bonding of two or more substituted 8-quinolinolate ligands) are useful as well for the light-emitting layer. Specific examples of such compounds include bis(2-methyl-8-quinolinolate)(para-phenylphenolate)aluminum (III), and bis(2-methyl-8-quinolinolate)(1-naphtholate)aluminum (III).

The above-described embodiments are only examples, and the present invention is not limited to them. For example, the color filter layer 93, 103 may have black matrices in its film-absent portions.

### EXAMPLES

The present invention will now be described more specifically by way of Examples.

### Example 1

Ten different gravure plates (G1-A to G1-J) in the form of sheets, having cells in the shape of stripes (the depth of the cells: 35 μm) extending in the direction of printing (the direction of rotation of the blanket cylinder), were prepared, in which the length L of the cell portions and the length S of the non-cell portions were changed over a range of 10 to 500 μm and a range of 2 to 500 μm, respectively, to vary, as shown in Table 1, the proportion of the length L of the cell portions to the length S of the non-cell portions S, L/S. The effective width of the gravure plates was 50 mm.

A red-light-emitting-layer-forming ink composition A1 having the following formulation was prepared. The coefficient of viscosity of this ink composition A1 (ink temperature: 23° C.), measured at a shear rate of 100 sec⁻¹ with a viscoelasticity meter Model MCR301 manufactured by Physica Corp. in the steady flow mode, was 80 cP. Further, using a tension meter Model CBVP-Z manufactured by Kyowa Kaimen Kagaku Kabushiki Kaisha, Japan, the surface tensions of mesitylene and tetralin, solvents, were measured at a liquid temperature of 20° C.

(Formulation of Red-Light-Emitting-Layer-Forming Ink Composition A1)

Polyfluorene Derivative
as red-light-emitting material (molecular weight: 300,000) 2.5 wt. %

Solvent
(50:50 solvent mixture of mesitylene and tetralin) 97.5 wt. %
(surface tension of the solvent mixture=32 dyne/cm, boiling point=186° C.)
(surface tension of mesitylene=28 dyne/cm, boiling point=165° C.)
(surface tension of tetralin=35.5 dyne/cm, boiling point=207° C.)

On the other hand, a hole-injection-layer-forming ink composition B1 having the following formulation was prepared. The coefficient of viscosity of this ink composition B1 (ink temperature: 23° C.), measured at a shear rate of 100 sec⁻¹ in the same manner as that in which the coefficient of viscosity of the ink composition A1 was measured, was 15 cP. The dynamic surface tension of the ink composition B1 (ink temperature: 23° C.) measured at 2 Hz with SITA t60/2 (manufactured by SITA Messtechnik GmbH, Germany) was 30 dyne/cm.

(Formulation of Hole-Injection-Layer-Forming Ink Composition B1)

PEDOT (poly(3,4)ethylenedioxythiophene)/PSS (polystyrenesulfonate) (mixture ratio=1/20) 70 wt. %
(Baytron PCH8000 manufactured by BAYER AG., Germany) Solvent Mixture 30 wt. %
(water: isopropyl alcohol (b.p. 82.4° C.)=70:30)

Further, an adherent polyethylene terephthalate (PET) film (U10 manufactured by Toray Industries, Inc., Japan, thickness: 100 μm, surface tension: 60 dyne/cm) was prepared as the resin film. The surface tension of this film was determined by measuring the contact angle θ with an automatic contact angle meter (DropMaster Model 700 manufactured by Kyowa Kaimen Kagaku Kabushiki Kaisha, Japan), using two or more liquids (standard substances) having known surface tensions, and calculating by using the equation: γs (surface tension of resin film)=γL (surface tension of liquid) cos θ+γSL (surface tension of resin film and liquid).

Subsequently, the above-described resin film was wound around the periphery of a blanket cylinder with a diameter of 12 cm and a cylinder width of 30 cm, having a cushion layer (hardness 70°) on its surface. The hardness of the cushion layer is the Type A hardness determined by the durometer hardness test prescribed by JIS K-6253.

Each one of the gravure plates and the blanket were then set on a flatbed offset press, and the red-light-emitting-layer-forming ink composition A1 or the hole-injection-layer-forming ink composition B1 was supplied to the gravure plate, while scraping the excess ink composition off with a blade, thereby filling the cells with the ink composition. A glass substrate subjected to both cleaning treatment and ultraviolet plasma cleaning was prepared as the substrate. After letting the blanket receive the ink composition from the gravure plate, the received ink composition was transferred to the glass substrate to form thereon a red light-emitting layer or a hole-injection layer. The printing speed was 1000 mm/sec, and the transferred ink composition was dried for 1 hour on a hot plate set to a temperature of 120° C.

Printability at the time the red light-emitting layers were formed by the use of the gravure plates different in the proportion of the length L of the cell portions to the length S of the non-cell portions, L/S, and printability at the time the hole-injection layers were formed by the use of these gravure plates were evaluated. The percentage of variations in thickness [(maximum thickness−minimum thickness)/mean thickness]×100 (%) and the mean thickness of each red light-emitting layer and those of each hole-injection layer were determined. The results are shown in Table 1. The thickness of each red light-emitting layer and that of each hole-injection layer were measured with Nanopics 1000 manufactured by Seiko Instruments Inc., Japan, using a standard cantilever for the contact mode of this apparatus, scanning an area of 100 μm at a speed of 90 sec/frame.

TABLE 1

| | | | | | | red light- | | | |
|---|---|---|---|---|---|---|---|---|---|
| | | | | printability | | emitting layer | | hole-injection layer | |
| | L/S in | L(μm) in | S(μm) in | red light- | hole- | mean | variations | mean | variations |
| gravure | gravure | gravure | gravure | emitting | injection | thickness | in thick- | thickness | in thick- |
| plate | plate | plate | plate | layer | layer | (nm) | ness (%) | (nm) | ness (%) |
| G1-A | 0.5 | 40 | 80 | voids occurred | voids occurred | 60 | 20 | 40 | 20 |
| G1-B | 0.8 | 80 | 100 | excellent | excellent | 80 | 10 | 52 | 10 |
| G1-C | 1 | 100 | 100 | excellent | excellent | 85 | 7 | 57 | 7 |
| G1-D | 3 | 120 | 40 | excellent | excellent | 105 | 4 | 72 | 4 |
| G1-E | 5 | 150 | 30 | excellent | excellent | 120 | 4 | 75 | 4 |
| G1-F | 10 | 130 | 13 | excellent | excellent | 102 | 4 | 65 | 4 |
| G1-G | 20 | 200 | 10 | excellent | excellent | 110 | 5 | 70 | 6 |
| G1-H | 60 | 300 | 5 | excellent | excellent | 100 | 8 | 60 | 8 |
| G1-I | 100 | 300 | 3 | excellent | excellent | 90 | 10 | 55 | 10 |
| G1-J | 150 | 450 | 3 | non-uniform | non-uniform | 60 | 20 | 45 | 25 |
| | | | | in density | in density | | | | |

The data shown in Table 1 demonstrate that practical red light-emitting layers (thickness: 70 nm or more) and practical hole-injection layers (thickness: 50 nm or more) can be obtained when the gravure plates G1-B to G1-I in which the proportion of the length L of the cell portions to the length S of the non-cell portions, L/S, is from 0.8 to 100 are used.

### Example 2

Nine different gravure plates (G2-A to G2-I) in the form of sheets, having cells in the shape of stripes (the depth of the cells: 35 μm) extending in the direction of printing (the direction of rotation of the blanket cylinder), were prepared, in which the length L of the cell portions and the length S of the non-cell portions were varied as shown in Table 2 so that the proportion of the length L of the cell portions to the length S of the non-cell portions, L/S, fell in the range of 1 to 10. The effective width of the gravure plates was 50 mm.

Red light-emitting layers and hole-injection layers were formed in the same manner as in Example 1, except that the above-described gravure plates were used instead of the gravure plates used in Example 1.

Printability at the time the red light-emitting layers were formed by the use of the gravure plates different in both the length L of the cell portions and the length S of the non-cell portions, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 2.

TABLE 2

| | | | | | | red light- | | | |
|---|---|---|---|---|---|---|---|---|---|
| | | | | printability | | emitting layer | | hole-injection layer | |
| | L/S in | L(μm) in | S(μm) in | red light- | hole- | mean | variations | mean | variations |
| gravure | gravure | gravure | gravure | emitting | injection | thickness | in thick- | thickness | in thick- |
| plate | plate | plate | plate | layer | layer | (nm) | ness (%) | (nm) | ness (%) |
| G2-A | 10 | 500 | 50 | excellent | excellent | 85 | 10 | 55 | 10 |
| G2-B | 1.5 | 300 | 200 | excellent | excellent | 90 | 5 | 55 | 7 |
| G2-C | 10 | 100 | 10 | excellent | excellent | 100 | 4 | 65 | 5 |
| G2-D | 10 | 600 | 60 | non-uniform | non-uniform | 60 | 20 | 45 | 20 |
| | | | | in density | in density t | | | | |
| G2-E | 10 | 50 | 1 | difficult to | difficult to | 50 | 30 | 30 | 40 |
| | | | | make cells | make cells | | | | |
| G2-F | 6 | 30 | 5 | excellent | excellent | 80 | 8 | 55 | 10 |
| G2-G | 5 | 10 | 2 | excellent | excellent | 80 | 10 | 50 | 10 |
| G2-H | 10 | 10 | 1 | difficult to | difficult to | 50 | 35 | 30 | 40 |
| | | | | make cells | make cells | | | | |
| G2-I | 5 | 5 | 1 | difficult to | difficult to | 40 | 40 | 20 | 40 |
| | | | | make cells | make cells | | | | |

The data shown in Table 2 demonstrate that practical red light-emitting layers (thickness: 70 nm or more) and practical hole-injection layers (thickness: 50 nm or more) can be obtained when the gravure plates G2-A to G2-C, G2-F, and G2-G in which the length L of the cell portions L and the length S of the non-cell portions are from 10 to 500 μm and from 2 to 500 μm, respectively, are used.

### Example 3

Seven different gravure plates (G3-A to G3-G) in the form of sheets, varying in depth as shown in Table 3, having cells in the shape of stripes extending in the direction of printing (the direction of rotation of the blanket cylinder), were prepared, in which the length L of the cell portions and the length S of the non-cell portions S were made 120 μm and 30 μm, respectively (the proportion L/S was 4). The effective width of the gravure plates was 50 mm.

Red light-emitting layers and hole-injection layers were formed in the same manner as in Example 1, except that the above-described gravure plates were used instead of the gravure plates used in Example 1.

Printability at the time the red light-emitting layers were formed by the use of the gravure plates different in depth, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 3.

TABLE 3

| | | | | red light- | | | |
|---|---|---|---|---|---|---|---|
| | | printability | | emitting layer | | hole-injection layer | |
| | depth of | red light- | hole- | mean | variations | mean | variations |
| gravure | gravure | emitting | injection | thickness | in thick- | thickness | in thick- |
| plate | plate (μm) | layer | layer | (nm) | ness (%) | (nm) | ness (%) |
| G3-A | 10 | excellent | excellent | 50 | 4 | 30 | 4 |
| G3-B | 20 | excellent | excellent | 80 | 4 | 50 | 4 |
| G3-C | 30 | excellent | excellent | 110 | 4 | 70 | 4 |
| G3-D | 50 | excellent | excellent | 120 | 4 | 70 | 5 |
| G3-E | 100 | excellent | excellent | 100 | 6 | 70 | 8 |
| G3-F | 200 | excellent | excellent | 90 | 10 | 60 | 10 |
| G3-G | 250 | non-uniform | non-uniform | 70 | 25 | 50 | 30 |
| | | in density | in density | | | | |

The data shown in Table 3 demonstrate that practical red light-emitting layers (thickness: 70 nm or more) and practical hole-injection layers (thickness: 50 nm or more) can be obtained when the gravure plates G3-B to G3-F having depths of 20 to 200 μm are used.

### Example 4

Six different gravure plates (G4-A to G4-F) in the form of sheets, having cells in the shape of stripes (the depth of the cells: 35 μm), the length L of the cell portions being 120 μm, the length S of the non-cell portions being 30 μm, the proportion L/S being 4, were prepared, in which the proportion of the width b of each cell measured in the direction of printing (the direction of rotation of the blanket cylinder) to the width a of each cell measured in the direction perpendicular to the direction of printing, b/a, was varied as shown in Table 4. The effective width of the gravure plates was 50 mm.

Red light-emitting layers and hole-injection layers were formed in the same manner as in Example 1, except that the above-described gravure plates were used instead of the gravure plates used in Example 1.

Printability at the time the red light-emitting layers were formed by the use of the gravure plates different in the proportion b/a, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 4.

TABLE 4

| | | | | red light- | | | |
|---|---|---|---|---|---|---|---|
| | proportion | printability | | emitting layer | | hole-injection layer | |
| | b/a in | red light- | hole- | mean | variations | mean | variations |
| gravure | gravure | emitting | injection | thickness | in thick- | thickness | in thick- |
| plate | plate | layer | layer | (nm) | ness (%) | (nm) | ness (%) |
| G4-A | 0.5 | Lacking in | Lacking in | 60 | 10 | 40 | 10 |
| | | uniformity | uniformity | | | | |
| | | due to cells | due to cells | | | | |
| G4-B | 0.6 | excellent | excellent | 80 | 8 | 50 | 8 |
| G4-C | 0.8 | excellent | excellent | 90 | 7 | 60 | 8 |
| G4-D | 1 | excellent | excellent | 110 | 6 | 70 | 6 |
| G4-E | 2 | excellent | excellent | 105 | 4 | 75 | 4 |
| G4-F | 1000 | excellent | excellent | 100 | 4 | 75 | 4 |

The data shown in Table 4 demonstrate that practical red light-emitting layers (thickness: 70 nm or more) and practical hole-injection layers (thickness: 50 nm or more) can be obtained when the gravure plates G4-B to G4-F in which the proportion b/a is 0.6 or more are used.

### Example 5

Six different gravure plates (G5-A to G5-F) in the form of sheets, having a plurality of rectangular cells (depth: 35 μm) arranged in a grid pattern, the length L of the cell portions being 100 μm, the length S of the non-cell portions being 25 μm, the long side of each cell making a proper angle with the direction of printing (the direction of rotation of the blanket cylinder), were prepared, in which the proportion of the maximum width b of each cell measured in the direction of printing to the maximum width a of each cell measured in the direction perpendicular to the direction of printing, b/a, was varied as shown in Table 5. The effective width of the gravure plates was 50 mm, and the percentage of the whole cell area to the film-formed area in the gravure plates was from 68 to 72%.

Red light-emitting layers and hole-injection layers were formed in the same manner as in Example 1, except that the above-described gravure plates were used instead of the gravure plates used in Example 1.

Printability at the time the red light-emitting layers were formed by the use of the gravure plates different in the proportion b/a, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 5.

TABLE 5

| | | | | red light- | | | |
|---|---|---|---|---|---|---|---|
| | proportion | printability | | emitting layer | | hole-injection layer | |
| | b/a in | red light- | hole- | mean | variations | mean | variations |
| gravure | gravure | emitting | injection | thickness | in thick- | thickness | in thick- |
| plate | plate | layer | layer | (nm) | ness (%) | (nm) | ness (%) |
| G5-A | 0.5 | Lacking in | Lacking in | 60 | 10 | 40 | 10 |
| | | uniformity | uniformity | | | | |
| | | due to cells | due to cells | | | | |
| G5-B | 0.6 | excellent | excellent | 80 | 8 | 50 | 9 |
| G5-C | 0.8 | excellent | excellent | 85 | 8 | 55 | 7 |
| G5-D | 1.0 | excellent | excellent | 90 | 7 | 60 | 7 |
| G5-E | 1.5 | excellent | excellent | 90 | 5 | 60 | 6 |
| G5-F | 2.0 | excellent | excellent | 95 | 5 | 65 | 5 |

The data shown in Table 5 demonstrate that practical red light-emitting layers (thickness: 70 nm or more) and practical hole-injection layers (thickness: 50 nm or more) can be obtained when the gravure plates G5-B to G5-F in which the proportion b/a is 0.6 or more are used.

### Example 6

Six different gravure plates (G6-A to G6-F) in the form of sheets, having rectangular (200 μm×100 μm) cells (depth: 35 μm) arranged in a grid pattern, were prepared, in which the length S of the non-cell portions was changed over a range of 10 to 500 μm to vary, as shown in Table 6, the percentage of the whole cell area to the film-formed area. The effective width of the gravure plates was 50 mm. The angle of the long side of each cell relative to the direction of printing (the direction of rotation of the blanket cylinder) was 0°, and the proportion of the width b of each cell measured in the direction of printing to the width a of each cell measured in the direction perpendicular to the direction of printing, b/a, was 2.

Red light-emitting layers and hole-injection layers were formed in the same manner as in Example 1, except that the above-described gravure plates were used instead of the gravure plates used in Example 1.

Printability at the time when the red light-emitting layers were formed by the use of the gravure plates different in percentage of the whole cell area, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 6.

TABLE 6

| | percentage | | | red light- | | | |
|---|---|---|---|---|---|---|---|
| | of whole | printability | | emitting layer | | hole-injection layer | |
| | cell area of | red light- | hole- | mean | variations | mean | variations |
| gravure | gravure | emitting | injection | thickness | in thick- | thickness | in thick- |
| plate | plate (%) | layer | layer | (nm) | ness (%) | (nm) | ness (%) |
| G6-A | 50 | excellent | excellent | 60 | 4 | 30 | 4 |
| G6-B | 55 | excellent | excellent | 80 | 4 | 50 | 4 |
| G6-C | 60 | excellent | excellent | 90 | 4 | 60 | 4 |
| G6-D | 90 | excellent | excellent | 90 | 6 | 60 | 6 |
| G6-E | 95 | excellent | excellent | 80 | 10 | 50 | 10 |
| G6-F | 97 | non-uniform | non-uniform | 60 | 20 | 35 | 25 |
| | | in density | in density | | | | |

The data shown in Table 6 demonstrate that practical red light-emitting layers (thickness: 70 nm or more) and practical hole-injection layers (thickness: 50 nm or more) can be obtained when the gravure plates G6-B to G6-E in which the percentage of the whole cell area is from 55 to 95% are used.

### Example 7

Six different gravure plates (G7-A to G7-F) in the form of sheets, varying in depth as shown in Table 7, having rectangular (200 μm×100 μm) cells arranged in a grid pattern, were prepared, in which the length S of the non-cell portions was made 25 μn, the long side of each cell was made parallel to the direction of printing (the direction of rotation of the blanket cylinder), and the proportion of the maximum width b of each cell measured in the direction of printing to the maximum width a of each cell measured in the direction perpendicular to the direction of printing, b/a, was made 2. The effective width of the gravure plates was 50 mm, and the percentage of the whole cell area to the film-formed area in the gravure plates was 64%.

Red light-emitting layers and hole-injection layers were formed in the same manner as in Example 1, except that the above-described gravure plates were used instead of the gravure plates used in Example 1.

Printability at the time the red light-emitting layers were formed by the use of the gravure plates different in depth, and printability at the time the hole-injection layers were formed by the use of these gravure plates were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 7.

TABLE 7

| | | | | red light- | | | |
|---|---|---|---|---|---|---|---|
| | | printability | | emitting layer | | hole-injection layer | |
| | depth of | red light- | hole- | mean | variations | mean | variations |
| gravure | gravure | emitting | injection | thickness | in thick- | thickness | in thick- |
| plate | plate (μm) | layer | layer | (nm) | ness (%) | (nm) | ness (%) |
| G7-A | 10 | excellent | excellent | 50 | 3 | 30 | 3 |
| G7-B | 20 | excellent | excellent | 80 | 4 | 50 | 4 |
| G7-C | 30 | excellent | excellent | 90 | 4 | 65 | 5 |
| G7-D | 100 | excellent | excellent | 85 | 6 | 60 | 8 |
| G7-E | 200 | excellent | excellent | 80 | 10 | 50 | 10 |
| G7-F | 250 | non-uniform | non-uniform | 60 | 15 | 35 | 20 |
| | | in density | in density | | | | |

The data shown in Table 7 demonstrate that practical red light-emitting layers (thickness: 70 nm or more) and practical hole-injection layers (thickness: 50 nm or more) can be obtained when the gravure plates G7-B to G7-E having depths of 20 to 200 μm are used.

### Example 8

A gravure plate (G8) in the form of a sheet, having cells in the shape of stripes (depth: 35 μm) extending in the direction of printing (the direction of rotation of the blanket cylinder), was prepared, in which the length L of the cell portions and the length S of the non-cell portions were made 120 μm and 30 μm, respectively (the proportion L/S was 4). The effective width of the gravure plates was 50 mm.

The following five resin films (F1 to F5) different in surface tension were prepared as the resin films.

(Resin Films)

F1: Polypropylene film (Torephane BO, Type 2500, manufactured by Toray Industries, Inc., Japan; thickness 50 μm; surface tension 30 dyne/cm).
F2: Melamine-baked polyethylene terephthalate film (PET100SG-1, manufactured by Panack Kabushiki Kaisha, Japan; thickness 100 μm; surface tension 35 dyne/cm).
F3: Polyethylene terephthalate film (T60 manufactured by Toray Industries, Inc., Japan; thickness 75 μm; surface tension 38 dyne/cm).
F4: Polyethylene naphthalate film (Q51 manufactured by TEIJIN LIMITED, Japan; thickness 75 μm; surface tension dyne/cm).
F5: Adherent polyethylene terephthalate film (U10 manufactured by Toray Industries, Inc., Japan; thickness 100 μm; surface tension 60 dyne/cm).

Subsequently, each one of the above-described resin films (F1 to F5) was wound around the periphery of the same blanket cylinder as that used in Example 1, thereby obtaining 5 different blankets.

The gravure plate and each blanket described above were then set on a flatbed offset press, and a red light-emitting layer and a hole-injection layer were formed in the same manner as in Example 1.

Printability at the time the red light-emitting layers were formed by the use of the blankets with the resin films different in surface tension, and printability at the time the hole-injection layers were formed by the use of these blankets were evaluated. Further, the percentage of variations in thickness [(maximum thickness−minimum thickness)/mean thickness]×100 (%) and the mean thickness of each red light-emitting layer and those of each hole-injection layer were determined in the same manner as in Example 1. The results are shown in Table 8.

TABLE 8

| | | | | red light- | | | |
|---|---|---|---|---|---|---|---|
| | | printability | | emitting layer | | hole-injection layer | |
| resin film | surface tension | red light- | hole- | mean | variations | mean | variations |
| used for | of resin film | emitting | injection | thickness | in thick- | thick- | in thick- |
| blanket | (Dyne/cm) | layer | layer | (nm) | ness (%) | ness (nm) | ness (%) |
| F1 | 30 | poor in | poor in | 40 | 20 | 10 | 40 |
| | | receptivity | receptivity | | | | |
| | | to ink from | to ink from | | | | |
| | | gravure plate | gravure plate | | | | |
| F2 | 35 | excellent | excellent | 90 | 10 | 50 | 10 |
| F3 | 38 | excellent | excellent | 110 | 4 | 50 | 10 |
| F4 | 45 | excellent | excellent | 110 | 6 | 60 | 8 |
| F5 | 60 | excellent | excellent | 100 | 4 | 70 | 4 |

The data shown in Table 8 demonstrate that practical red light-emitting layers (thickness: 70 nm or more) and practical hole-injection layers (thickness: 50 nm or more) can be obtained when the blankets with the resin films F2 to F5 having surface tensions of 35 dyne/cm or more are used.

### Example 9

Eight different red-light-emitting-layer-forming ink compositions (A1-1 to A1-8) were prepared on the basis of the formulation of the ink composition A1 used in Example 1, provided that solvent mixtures different in boiling point as shown in Table 9 were used instead of the solvent mixture used in Example 1.

On the other hand, the same gravure plate as the gravure plate G8 in Example 8 was prepared. The surface tensions of the solvent mixtures were 40 dyne or less, and the coefficients of viscosity of the ink compositions (ink temperature: 23° C.) at a shear rate of 100 sec⁻¹ were from 5 to 200 cP.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a red light-emitting layer was formed on a glass substrate in the same manner as in Example 1, using each one of the red-light-emitting-layer-forming ink compositions (A1-1 to A1-8). The drying conditions used were also the same as those used in Example 1.

Printability at the time the red light-emitting layers were formed by the use of the eight red-light-emitting-layer forming ink compositions prepared by using the solvent mixtures different in boiling point was evaluated. Further, the percentage of variations in thickness [(maximum thickness−minimum thickness)/mean thickness]×100 (%) and the mean thickness of each red light-emitting layer were determined in the same manner as in Example 1. The results are shown in Table 9.

TABLE 9

| red light- | | | red light- | |
|---|---|---|---|---|
| emitting layer | boiling | | emitting layer | |
| ink | point of | | mean | variations |
| composition | solvent | | thickness | in thick- |
| used | (° C.) | printability | (nm) | ness (%) |
| A1-1 | 110 | ink dried up in the | — | — |
| | | course of filling of | | |
| | | ink into cells | | |
| A1-2 | 140 | immediately after | 80 | 50 |
| | | transferred to | | |
| | | substrate, ink dried | | |
| | | up, and streaks were | | |
| | | formed | | |
| A1-3 | 150 | streaks were slightly | 90 | 10 |
| | | formed | | |
| A1-4 | 165 | streaks were slightly | 100 | 8 |
| | | formed | | |
| A1-5 | 210 | excellent | 110 | 5 |
| A1-6 | 240 | excellent | 105 | 5 |
| A1-7 | 250 | excellent | 100 | 5 |
| A1-8 | 270 | not dried in drying | 100 | 5 |
| | | zone | | |

The data shown in Table 9 demonstrate that practical red light-emitting layers (thickness: 70 nm or more) can be obtained when the ink compositions (A1-3 to A1-7) prepared by using the solvent mixtures having boiling points of 150 to 250° C. are used.

### Example 10

Eight different red-light-emitting-layer-forming ink compositions (A2-1 to A2-8) were prepared on the basis of the formulation of the ink composition A1 used in Example 1, provided that solvent mixtures different in surface tension as shown in Table 10 were used instead of the solvent mixture used in Example 1. The boiling points of the solvent mixtures were from 150 to 250° C., and the coefficients of viscosity of the ink compositions (ink temperature: 23° C.) at a shear rate of 100 sec⁻¹ were from 5 to 200 cP.

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a red light-emitting layer was formed on a glass substrate in the same manner as in Example 1, using each one of the red-light-emitting-layer-forming ink compositions (A2-1 to A2-8). The drying conditions used were also the same as those used in Example 1.

Printability at the time when the red light-emitting layers were formed by the use of the eight red-light-emitting-layer-forming ink compositions prepared by using the solvent mixtures different in surface tension was evaluated. Further, the percentage of variations in thickness [(maximum thickness−minimum thickness)/mean thickness]×100 (%) and the mean thickness of each red light-emitting layer were determined in the same manner as in Example 1. The results are shown in Table 10.

TABLE 10

| red light- | | | red light- | |
|---|---|---|---|---|
| emitting layer | surface | | emitting layer | |
| ink | tension of | | mean | variations |
| composition | solvent | | thickness | in thick- |
| used | (Dyne/cm) | printability | (nm) | ness (%) |
| A2-1 | 25 | excellent | 110 | 5 |
| A2-2 | 30 | excellent | 110 | 4 |
| A2-3 | 32 | excellent | 110 | 2 |
| A2-4 | 34 | excellent | 100 | 4 |
| A2-5 | 36 | some ridges are | 95 | 7 |
| | | present in edge | | |
| | | portions | | |
| A2-6 | 38 | some ridges are | 90 | 8 |
| | | present in edge | | |
| | | portions | | |
| A2-7 | 40 | some ridges are | 80 | 10 |
| | | present in edge | | |
| | | portions | | |
| A2-8 | 42 | poor in receptivity | 60 | 25 |
| | | to ink from | | |
| | | gravure plate | | |

The data shown in Table 10 demonstrate that practical red light-emitting layers (thickness: 70 nm or more) can be obtained when the ink compositions (A2-1 to A2-7) prepared by using the solvent mixtures having surface tensions of 40 dyne/cm or less are used.

### Example 11

Twelve different red-light-emitting-layer-forming ink compositions (A3-1 to A3-12) varying, as shown in Table 11, in coefficient of viscosity (ink temperature: 23° C.) at a shear rate of 100 sec⁻¹ from 3 to 250 cP were prepared on the basis of the formulation of the ink composition A1 used in Example 1, provided that the red-light-emitting material content was changed over a range of 2 to 3% by weight, and that the mixture ratio of mesitylene and tetralin, constituents of the solvent mixture, was changed so that the solvent mixture had a surface tension of 25 to 40 dyne/cm and a boiling point of 150 to 250° C.

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a red light-emitting layer was formed on a glass substrate in the same manner as in Example 1, using each one of the red-light-emitting-layer-forming ink compositions (A3-1 to A3-12). The drying conditions used were also the same as those used in Example 1.

Printability at the time the red light-emitting layers were formed by the use of the twelve red-light-emitting-layer-forming ink compositions different in coefficient of viscosity was evaluated. Further, the percentage of variations in thickness [(maximum thickness−minimum thickness)/mean thickness]×100 (%) and the mean thickness of each red light-emitting layer were determined in the same manner as in Example 1. The results are shown in Table 11.

TABLE 11

| red light- | | | red light- | |
|---|---|---|---|---|
| emitting layer | | | emitting layer | |
| ink | viscosity | | mean | variations |
| composition | of ink | | thickness | in thick- |
| used | (cP) | printability | (nm) | ness (%) |
| A3-1 | 3 | runs occurred | 50 | 40 |
| A3-2 | 5 | mottled | 70 | 10 |
| A3-3 | 10 | slightly mottled | 85 | 10 |
| A3-4 | 20 | slightly mottled | 100 | 7 |
| A3-5 | 30 | excellent | 100 | 5 |
| A3-6 | 50 | excellent | 105 | 3 |
| A3-7 | 80 | excellent | 105 | 3 |
| A3-8 | 90 | excellent | 105 | 3 |
| A3-9 | 100 | excellent | 100 | 5 |
| A3-10 | 150 | some cell marks | 90 | 7 |
| | | are present | | |
| A3-11 | 200 | cell marks are | 80 | 10 |
| | | present | | |
| A3-12 | 250 | roughened by | 45 | 30 |
| | | cell marks | | |

The data shown in Table 11 demonstrate that practical red light-emitting layers (thickness: 70 nm or more) can be obtained when the ink compositions (A3-2 to A3-11) having coefficients of viscosity of 5 to 200 cP are used.

### Example 12

Seven different hole-injection-layer-forming ink compositions (B1-1 to B1-7) were prepared on the basis of the formulation of the ink composition B1 used in Example 1, provided that alcoholic solvents different in boiling point as shown in Table 12 were used instead of the alcoholic solvent used in Example 1. These ink compositions had coefficients of viscosity of 1 to 100 cP (ink temperature: 23° C.) at a shear rate of 100 sec⁻¹ and dynamic surface tensions of 40 dyne/cm or less (ink temperature: 23° C.) at 2 Hz.

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a hole-injection layer was formed on a glass substrate in the same manner as in Example 1, using each one of the hole-injection-layer-forming ink compositions (B1-1 to B1-7). The drying conditions used were also the same as those used in Example 1.

Printability at the time the hole-injection layers were formed by the use of the seven hole-injection-layer-forming ink compositions prepared by using the alcoholic solvents different in boiling point was evaluated. Further, the percentage of variations in thickness [(maximum thickness−minimum thickness)/mean thickness]×100 (%) and the mean thickness of each hole-injection layer were determined in the same manner as in Example 1. The results are shown in Table 12.

TABLE 12

| hole-injection- | boiling | | | |
|---|---|---|---|---|
| layer-forming | point of | | hole-injection layer | |
| ink | alcoholic | | mean | variations |
| composition | solvent | | thickness | in thick- |
| used | (° C.) | printability | (nm) | ness (%) |
| B1-1 | 64.5 | some streaks are | 60 | 10 |
| | | present | | |
| B1-2 | 78 | excellent | 65 | 8 |
| B1-3 | 82.4 | excellent | 70 | 4 |
| B1-4 | 150 | excellent | 55 | 5 |
| B1-5 | 200 | excellent | 50 | 5 |
| B1-6 | 250 | excellent | 50 | 5 |
| B1-7 | 270 | not dried in drying | — | — |
| | | zone | | |

The data shown in Table 12 demonstrate that practical hole-injection layers (thickness: 50 nm or more) can be obtained when the ink compositions (B1-2 to B1-6) prepared by using the alcoholic solvents having boiling points of 250° C. or less are used.

### Example 13

Six different hole-injection-layer-forming ink compositions (B2-1 to B2-6) having dynamic surface tensions of 25 to 70 dyne/cm (ink temperature: 23° C.) at 2 Hz were prepared on the basis of the formulation of the ink composition B1 used in Example 1, provided that the PEDOT/PSS content of the ink composition was changed over a range of 0.3 to 10% by weight without changing the mixture ratio of PEDOT and PSS, and that the mixture ratio of water and isopropyl alcohol (IPA), constituents of the solvent mixture, was changed over a range of 95:5 to 30:70 (IPA content: 5 to 70% by weight). The coefficients of viscosity of these ink compositions at a shear rate of 100 sec⁻¹ were from 1 to 100 cP (ink temperature: 23° C.).

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a hole-injection layer was formed on a glass substrate in the same manner as in Example 1, using each one of the hole-injection-layer-forming ink compositions (B2-1 to B2-6). The drying conditions used were also the same as those used in Example 1.

Printability at the time the hole-injection layers were formed by the use of the six hole-injection-layer-forming ink compositions different in dynamic surface tension at 2 Hz was evaluated. Further, the percentage of variations in thickness [(maximum thickness−minimum thickness)/mean thickness]×100 (%) and the mean thickness of each hole-injection layer were determined in the same manner as in Example 1. The results are shown in Table 13.

TABLE 13

| hole-injection- | dynamic | | | |
|---|---|---|---|---|
| layer-forming | surface | | hole-injection layer | |
| ink | tension of ink | | mean | variations |
| composition | composition | | thickness | in thick- |
| used | (Dyne/cm) | printability | (nm) | ness (%) |
| B2-1 | 25 | excellent | 70 | 4 |
| B2-2 | 30 | excellent | 70 | 5 |
| B2-3 | 35 | excellent | 70 | 5 |
| B2-4 | 40 | excellent | 50 | 10 |
| B2-5 | 50 | insufficient | 25 | 10 |
| | | in receptivity | | |
| | | to ink from | | |
| | | gravure plate | | |
| B2-6 | 70 | poor in | 5 | 10 |
| | | receptivity | | |
| | | to ink from | | |
| | | gravure | | |

The data shown in Table 13 demonstrate that practical hole-injection layers (thickness: 50 nm or more) can be obtained when the ink compositions (B2-1 to B2-4) whose dynamic surface tensions at 2 Hz are 40 dyne/cm or less are used.

### Example 14

Nine different hole-injection-layer-forming ink compositions (B3-1 to B3-9) varying, as shown in Table 14, in coefficient of viscosity at a shear rate of 100 sec⁻¹ from 0.5 to 120 cP (ink temperature: 23° C.) were prepared on the basis of the formulation of the ink composition B1 used in Example 1, provided that the PEDOT/PSS content of the ink composition was changed over a range of 0.3 to 10% by weight without changing the mixture ratio of PEDOT and PSS, and that the mixture ratio of water and isopropyl alcohol, constituents of the solvent mixture, was changed over a range of 95:5 to 30:70. The dynamic surface tensions of these ink compositions were from 20 to 40 dyne/cm (ink temperature: 23° C.) at 2 Hz.

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a hole-injection layer was formed on a glass substrate in the same manner as in Example 1, using each one of the hole-injection-layer-forming ink compositions (B3-1 to B3-9). The drying conditions used were also the same as those used in Example 1.

Printability at the time the hole-injection layers were formed by the use of the nine hole-injection-layer-forming ink compositions different in coefficient of viscosity was evaluated. Further, the percentage of variations in thickness [(maximum thickness−minimum thickness)/mean thickness]×100 (%) and the mean thickness of each hole-injection layer were determined in the same manner as in Example 1. The results are shown in Table 14.

TABLE 14

| hole-injection- | | | | |
|---|---|---|---|---|
| layer-forming | Viscosity | | hole-injection layer | |
| ink | of ink | | mean | variations |
| composition | composition | | thickness | in thick- |
| used | (Dyne/cm) | printability | (nm) | ness (%) |
| B3-1 | 0.5 | mottled | 20 | 25 |
| B3-2 | 1 | slightly mottled | 50 | 10 |
| B3-3 | 10 | excellent | 60 | 7 |
| B3-4 | 30 | excellent | 70 | 5 |
| B3-5 | 50 | excellent | 70 | 5 |
| B3-6 | 70 | excellent | 70 | 5 |
| B3-7 | 90 | excellent | 60 | 6 |
| B3-8 | 100 | some cell marks | 60 | 10 |
| | | are present | | |
| B3-9 | 120 | roughened by | 40 | 25 |
| | | cell marks | | |

The data shown in Table 14 demonstrate that practical hole-injection layers (thickness: 50 nm or more) can be obtained when the ink compositions (B3-2 to B3-8) having coefficients of viscosity of 1 to 100 cP are used.

### Example 15

Seven different hole-injection-layer-forming ink compositions (B4-1 to B4-7) were prepared on the basis of the formulation of the ink composition B1 used in Example 1, provided that water—isopropyl alcohol (IPA) solvent mixtures different in IPA content as shown in Table 15 were used instead of the solvent mixture used in Example 1. These ink compositions had coefficients of viscosity of 1 to 100 cP (ink temperature: 23° C.) at a shear rate of 100 sec⁻¹ and dynamic surface tensions of 40 dyne/cm or less (ink temperature: 23° C.) at 2 Hz.

On the other hand, the same gravure plate as the gravure plate G8 in Example 8 was prepared.

An adherent polyethylene terephthalate (PET) film (U10 manufactured by Toray Industries, Inc., Japan; thickness 100 μm; surface tension 60 dyne/cm), the resin film, was wound around the periphery of the same blanket cylinder as that used in Example 1, thereby obtaining a blanket.

The above-described gravure plate and blanket were then set on a flatbed offset press, and a hole-injection layer was formed on a glass substrate in the same manner as in Example 1, using each one of the hole-injection-layer-forming ink compositions (B4-1 to B4-7). The drying conditions used were also the same as those used in Example 1.

Printability at the time the hole-injection layers were formed by the use of the seven hole-injection-layer-forming ink compositions prepared by using the solvent mixtures different in IPA content was evaluated. Further, the percentage of variations in thickness [(maximum thickness−minimum thickness)/mean thickness]×100 (%) and the mean thickness of each hole-injection layer were determined in the same manner as in Example 1. The results are shown in Table 15.

TABLE 15

| hole-injection- | | | | |
|---|---|---|---|---|
| layer-forming | | | hole-injection layer | |
| ink | IPA content | | mean | variations |
| composition | of solvent | | thickness | in thick- |
| used | (wt. %)) | printability | (nm) | ness (%) |
| B4-1 | 3 | poor in | 10 | 40 |
| | | receptivity | | |
| | | to ink from | | |
| | | gravure plate | | |
| B4-2 | 5 | excellent | 50 | 10 |
| B4-3 | 20 | excellent | 70 | 5 |
| B4-4 | 35 | excellent | 70 | 5 |
| B4-5 | 50 | excellent | 60 | 5 |
| B4-6 | 70 | excellent | 50 | 10 |
| B4-7 | 80 | runs occurred | 30 | 25 |

The data shown in Table 15 demonstrate that practical hole-injection layers (thickness: 50 nm or more) can be obtained when the ink compositions (B4-2 to B4-6) prepared by using the solvent mixtures whose IPA contents are from 5 to 70% by weight are used.

### Example 16

(Formation of Transparent Electrode Layers)

First, an indium tin oxide (ITO) electrode film with a thickness of 200 nm was formed on a glass substrate (thickness: 0.7 mm) by ion plating. A photoresist was applied to this ITO electrode film. This photoresist film, covered with a mask, was exposed to light and was then developed. By etching the ITO electrode film, ten 2.2-mm wide transparent electrode layers in the shape of stripes were formed with a pitch of 4 mm.

(Formation of Insulating Layer)

Next, the glass substrate (thickness: 0.7 mm) described above was subjected to both cleaning treatment and ultraviolet plasma cleaning and was then spin-coated with a negative photosensitive resin. The photosensitive resin film was photolithographically patterned to form an insulating layer (thickness: 1 μm) having, on the transparent electrode layers, 2 mm×2 mm light-emitting areas (openings) with a pitch of 4 mm.

(Formation of Hole-Injection Layer)

The same gravure plate as that used in Example 8 was prepared.

The resin film F5 (U10 manufactured by Toray Industries, Inc., Japan; thickness 100 μm; surface tension 60 dyne/cm) described in Example 8 was wound around the periphery of the same blanket cylinder as that used in Example 1, thereby obtaining a blanket.

The above-described gravure plate and blanket were then set on a flatbed offset press, and a hole-injection layer (thickness: approximately 70 nm) was formed in the same manner as in Example 1, using the hole-injection-layer-forming ink composition B1 used in Example 1 (coefficient of viscosity (ink temperature: 23° C.) at a shear rate of 100 sec⁻¹:15 cP, dynamic surface tension (ink temperature: 23° C.) at 2 Hz: 30 dyne/cm, IPA content of solvent mixture of water and IPA (boiling point=82.4° C.): 30% by weight).

(Formation of Red Light-Emitting Layer)

The same gravure plate as that used in Example 8 was prepared.

The resin film F5 (U10 manufactured by Toray Industries, Inc., Japan; thickness 100 μm; surface tension 60 dyne/cm) described in Example 8 was wound around the periphery of the same blanket cylinder as that used in Example 1, thereby obtaining a blanket.

The above-described gravure plate and blanket were then set on a flatbed offset press, and a red light-emitting layer (thickness: approximately 100 nm) was formed in the same manner as in Example 1 on the hole-injection layer, using the red-light-emitting-layer-forming ink composition A1 used in Example 1 (coefficient of viscosity (ink temperature: 23° C.) at a shear rate of 100 sec⁻¹:80 cP, surface tension of the solvent mixture: 32 dyne/cm, boiling point of the solvent mixture: 186° C.).

(Formation of Electron-injection Layers)

A metal mask having 2.2-mm wide openings in the shape of stripes with a pitch of 4 mm was placed on the red light-emitting layer so that these openings crossed the above-described transparent electrode layers at right angles and were positioned on the light-emitting areas (openings) of the above-described insulating layer. Thereafter, calcium was vacuum-deposited (rate of deposition=0.1 nm/sec) on the red light-emitting layer covered with the mask, thereby forming ten electron-injection layers (thickness: 10 nm) with a pitch of 4 mm.

(Formation of Electrode Layers)

Aluminum was vacuum-deposited (rate of deposition=0.4 nm/sec) on the electron-injection layers, without removing the metal mask used in forming the electron-injection layers, whereby 2.2-wide aluminum-made electrode layers (thickness: 300 nm) in the shape of stripes were formed on the electron-injection layers.

Finally, a sealing sheet was laminated to the electrode layer face by an ultraviolet-curing adhesive. Thus, an organic light-emitting device of the present invention was obtained.

The emission efficiency at 1000 cd/m² and the life of this organic light-emitting device were evaluated. The life is herein defined as the time taken for the luminance of emitted light to become half in constant-current operation. As a result, the emission efficiency was 1.0 cd/A, and the life of the device was 100,000 hours. In the evaluation of the life of the device, the electric current value was set so that the initial luminance was 100 cd/m², and the time taken for the luminance to become half, 50 cd/m², was measured while continuously operating the device at the current.

### Comparative Example

An organic light-emitting device was obtained in the same manner as in Example 17, except that the gravure plate G4-A used in Example 4 (in which the proportion of the width b of each cell measured in the direction of printing (the direction of rotation of the blanket cylinder) to the width a of each cell measured in the direction perpendicular to the direction of printing, b/a, was 0.5) was used as the gravure plate. In this organic light-emitting device, the mean thickness of the hole-injection layer was 40 nm, and that of the red light-emitting layer was 60 nm.

The emission efficiency at 1000 cd/m² and the life of this organic light-emitting device, defined as the time taken for the luminance of emitted light to become half in constant-current operation, were evaluated. As a result, the emission efficiency was 0.6 cd/A, and the life of the device was 8,000 hours. Both the emission efficiency and the life of this device were inferior to those of the organic light-emitting device of Example 17.

### INDUSTRIAL UTILITY

The present invention is useful for the production of a variety of organic light-emitting devices such as full-color displays, area-color displays, and illuminations.

1. A gravure plate useful in forming a light-emitting layer and/or a hole-injection layer of an organic light-emitting device, comprising:
a plurality of cells in the shape of stripes, and
non-cell portions between the cells,
the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm.

2. A gravure plate useful in forming a light-emitting layer and/or a hole-injection layer of an organic light-emitting device, comprising:
narrow-belt-shaped non-cell portions that cross each other, and
a plurality of cells defined by the non-cell portions,
the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm.

3. A method for forming a light-emitting layer of an organic light-emitting device that comprises facing electrodes, and a light-emitting device layer having at least a light-emitting layer, formed between the facing electrodes,
by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or
a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm,
the method comprising the steps of:
filling the cells in the gravure plate with a light-emitting-layer-forming ink composition containing at least an organic light-emitting material and a solvent, and
after letting a blanket receive the light-emitting-layer-forming ink composition from the cells, transferring the light-emitting-layer-forming ink composition on the blanket to a face to be coated with a light-emitting layer,
the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension of 40 dyne/cm or less and a boiling point of 150 to 250° C.

4. The method for forming a light-emitting layer according to claim 3, wherein the resin film has a thickness ranging from 5 to 200 μm.

5. The method for forming a light-emitting layer according to claim 3, wherein the blanket has a blanket cylinder and the resin film integrally formed around the periphery of the blanket cylinder.

6. The method for forming a light-emitting layer according to claim 3, wherein the blanket has a blanket cylinder, and a resin film that winds round the rotating blanket cylinder in the section including at least a point at which the blanket receives the light-emitting-layer-forming ink composition from the gravure plate and a point at which the light-emitting-layer-forming ink composition is transferred to a face to be coated with a light-emitting layer.

7. The method for forming a light-emitting layer according to claim 5, wherein the blanket cylinder has, on its surface, a cushion layer.

8. The method for forming a light-emitting layer according to claim 3, wherein the content of the organic light-emitting material in the light-emitting-layer-forming ink composition is from 1.5 to 4.0% by weight.

9. The method for forming a light-emitting layer according to claim 3, wherein, in the gravure plate, a multitude of the cells form one area-color pattern, and the one pattern has a width of 200 μm or more.

10. The method for forming a light-emitting layer according to claim 3, wherein a plurality of light-emitting layers that emit light of different colors are sequentially formed by using two or more sets of the gravure plate and the blanket.

11. The method for forming a light-emitting layer according to claim 9, wherein the gravure plate is divided in the axial direction into a plurality of sections, and any light-emitting-layer-forming ink composition is supplied to each section, thereby simultaneously forming a plurality of light-emitting layers that emit light of different colors.

12. A method for forming a hole-injection layer of an organic light-emitting device that comprises facing electrodes, and a light-emitting device layer having at least a hole-injection layer and a light-emitting layer, formed between the facing electrodes,
by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, US, being from 0.8 to 100, the length L of each cell being from 10 to 500 μm, the length S of each non-cell portion being from 2 to 500 μm, the depth of the gravure plate being from 20 to 200 μm, or
a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm,
the method comprising the steps of:
filling the cells in the gravure plate with a hole-injection-layer-forming ink composition containing at least a hole-injection material and a solvent, and
after letting a blanket receive the hole-injection-layer-forming ink composition from the cells, transferring the hole-injection-layer-forming ink composition on the blanket to a face to be coated with a hole-injection layer,
the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

13. The method for forming a hole-injection layer according to claim 12, wherein the resin film has a thickness ranging from 5 to 200 μm.

14. The method for forming a hole-injection layer according to claim 12, wherein the blanket has a blanket cylinder and the resin film integrally formed around the periphery of the blanket cylinder.

15. The method for forming a hole-injection layer according to claim 12, wherein the blanket has a blanket cylinder, and a resin film that winds round the rotating blanket cylinder in the section including at least a point at which the blanket receives the hole-injection-layer-forming ink composition from the gravure plate and a point at which the hole-injection-layer-forming ink composition is transferred to a face to be coated with a hole-injection layer.

16. The method for forming a hole-injection layer according to claim 14, wherein the blanket cylinder has, on its surface, a cushion layer.

17. The method for forming a hole-injection layer according to claim 12, wherein the content of the hole-injection material in the hole-injection-layer-forming ink composition is from 0.3 to 10.0% by weight.

18. An organic light-emitting device comprising:
a transparent substrate,
a transparent electrode layer formed in the desired pattern on the transparent substrate,
an insulating layer having a plurality of openings in which the desired portions of the transparent electrode layer formed on the transparent substrate are exposed,
a light-emitting device layer having at least a light-emitting layer and a hole-injection layer, formed to cover the transparent electrode layer exposed at the bottom of the openings, and
an electrode layer formed so that it is in contact with the light-emitting device layer situated in the desired openings,
the light-emitting layer of the light-emitting device layer being formed by a method for forming a light-emitting layer of an organic light-emitting device that comprises facing electrodes, and a light-emitting device layer having at least a light-emitting layer, formed between the facing electrodes, by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a light-emitting-layer-forming ink composition containing at least an organic light-emitting material and a solvent, and after letting a blanket receive the light-emitting-layer-forming ink composition from the cells, transferring the light-emitting-layer-forming ink composition on the blanket to a face to be coated with a light-emitting layer, the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension of 40 dyne/cm or less and a boiling point of 150 to 250° C.,
the hole-injection layer of the light-emitting device layer being formed by a method for forming a hole-injection layer of an organic light-emitting device that comprises facing electrodes, and a light-emitting device layer having at least a hole-injection layer and a light-emitting layer, formed between the facing electrodes, by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the plate being from 20 to 200 μm, the method comprising the steps of filling the cells in the gravure plate with a hole-New injection-layer-forming ink composition containing at least a hole-injection material and a solvent, and after letting a blanket receive the hole-injection-layer-forming ink composition from the cells, transferring the hole-injection-layer-forming ink composition on the blanket to a face to be coated with a hole-injection layer, the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

19. An organic light-emitting device comprising:
a substrate,
an electrode layer formed in the desired pattern on the substrate,
an insulating layer having a plurality of openings in which the desired portions of the electrode layer formed on the substrate are exposed,
a light-emitting device layer having at least a light-emitting layer and a hole-injection layer, formed to cover the electrode layer exposed at the bottom of the openings, and
a transparent electrode layer formed so that it is in contact with the light-emitting device layer situated in the desired openings,
the light-emitting layer of the light-emitting device layer being formed by a method for forming a light-emitting layer of an organic light-emitting device that comprises facing electrodes, and a light-emitting device layer having at least a light-emitting layer, formed between the facing electrodes, by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a light-emitting-layer-forming ink composition containing at least an organic light-emitting material and a solvent, and after letting a blanket receive the light-emitting-layer-forming ink composition from the cells, transferring the light-emitting-layer-forming ink composition on the blanket to a face to be coated with a light-emitting layer, the blanket having, as its surface layer, a resin film having a surface tension of 35 dyne/cm or more, the light-emitting-layer-forming ink composition having a coefficient of viscosity of 5 to 200 cP (ink temperature: 23° C.) at a shear rate of 100 sec⁻¹, the solvent for use in the light-emitting-layer-forming ink composition having a surface tension of 40 dyne/cm or less and a boiling point of 150 to 250° C.,
the hole-injection layer of the light-emitting device layer being formed by a method for forming a hole-injection of an organic light-emitting device that comprises facing electrodes, and a light-emitting device layer having at least a hole-injection layer and a light-emitting layer, formed between the facing electrodes, by the use of a gravure plate comprising a plurality of cells in the shape of stripes, and non-cell portions between the cells, the proportion of the width b of each cell measured in the direction of printing to the width a of each cell measured in the direction perpendicular to the direction of printing, b/a, being 0.6 or more, the proportion of the length L of each cell to the length S of each non-cell portion, L/S, being from 0.8 to 100, the length L of each cell being from 10 to 500 μm, the length S of each non-cell portion being from 2 to 500 μm, the depth of the gravure plate being from 20 to 200 μm, or a gravure plate comprising narrow-belt-shaped non-cell portions that cross each other, and a plurality of cells defined by the non-cell portions, the proportion of the maximum width b of each cell measured in the direction of printing to the maximum width a of each cell measured in the direction perpendicular to the direction of printing, b/a, being 0.6 or more, the percentage of the whole cell area to the film-formed area being from 55 to 95%, the length S of each non-cell portion being from 2 to 500 μm, the depth of the gravure plate being from 20 to 200 μm, the method comprising the steps of filling the cells in the gravure plate with a hole-injection-layer-forming ink composition containing at least a hole-injection material and a solvent, and after letting a blanket receive the hole-injection-layer-forming ink composition from the cells, transferring the hole-injection-layer-forming ink composition on the blanket to a face to be coated with a hole-injection layer, the blanket having, as its surface layer, a resin film having a surface tension of 35 dyne/cm or more, the hole-injection-layer-forming ink composition having a coefficient of viscosity of 1 to 100 cP (ink temperature: 23° C.) at a shear rate of 100 sec⁻¹ and a dynamic surface tension of 40 dyne/cm or less (ink temperature: 23° C.) at 2 Hz, the solvent for use in the hole-injection-layer-forming ink composition being a solvent mixture of water and an alcoholic solvent, the boiling point of the alcoholic solvent being 250° C. or less, the alcoholic solvent content of the solvent mixture being from 5 to 70% by weight.

20. The organic light-emitting device according to claim 18, wherein the light-emitting layer and the hole-injection layer, constituent layers of the light-emitting device layer, have a thickness of 70 nm or more and a thickness of 50 nm or more, respectively.

21. The organic light-emitting device according to claim 18, wherein the light-emitting device layer consists of at least a hole-injection layer, a light-emitting layer, and an electron-injection layer that are laminated in the order stated.

22. The organic light-emitting device according to claim 18, being of passive matrix type.

23. The organic light-emitting device according to claim 18, being of active matrix type.

24. The organic light-emitting device according to claim 18, wherein the openings in the insulating layer have organic light-emitting posters with a maximum opening width of 10 mm or more.

25. The organic light-emitting device according to claim 18, further comprising a color filter layer formed on the transparent substrate or on the substrate.

26. The organic light-emitting device according to claim 25, further comprising a color-changing phosphor layer formed on the color filter layer.

27. The organic light-emitting device according to claim 18, wherein the light-emitting device layer emits light of the desired color including white, or light of the two or more desired colors that form a predetermined pattern.

28. The organic light-emitting device according to claim 26, wherein the light-emitting device layer emits blue light, and the color-changing phosphor layer has a green color-changing layer that changes the blue light into green fluorescence and emits this green fluorescence and a red color-changing layer that changes the blue light into red fluorescence and emits this red fluorescence.

29. The organic light-emitting device according to claim 18, comprising a hole-injection layer and a light-emitting layer that are formed in the following manner: a film for the light-emitting layer is formed within one minute after forming a film for the hole-injection layer, and these two films are simultaneously dried at a temperature of 100 to 200° C.
